(19) United States
(12) Patent Application Publication
(10) Pub. No.: US 2012/0279557 A1
(43) Pub. Date: Nov. 8, 2012

(54) FLOATING SUPPORT STRUCTURE FOR A SOLAR PANEL ARRAY

(75) Inventors: Phil Alwitt, Larkspur, CA (US); John De Maio, Novato, CA (US); Mark Moore, Richmond, CA (US); Ryan Bogart, San Francisco, CA (US); Sean Westbrook, Pacifica, CA (US); Daniel Thompson, San Rafael, CA (US)

(73) Assignee: SPG SOLAR, INC., Novato, CA (US)

(21) Appl. No.: 13/211,282

(22) Filed: Aug. 16, 2011

Related U.S. Application Data
(63) Continuation-in-part of application No. 11/264,285, filed on Oct. 31, 2005, now abandoned.
Application No. 11/264,285 is a continuation-in-part of application No. 11/861,226, filed on Sep. 25, 2007, now abandoned.
(60) Provisional application No. 61/492,224, filed on Jun. 1, 2011.
(60) Provisional application No. 60/623,328, filed on Oct. 29, 2004.

(51) Int. Cl. H01L 31/048; H01L 31/18

(52) U.S. Cl. 136/251; 29/890.033

(57) ABSTRACT

A modular floating support structure for a solar panel array, each array module including floatation elements, a framework comprising E-W frame members connected to and aligning the floatation elements as well as N-S frame members providing a base on which panel supports are installed, and coupling hardware for connecting array modules to adjoining modules in both the E-W direction and N-S direction. A wireway/walkway may be disposed between and connect two large array fields. A mooring and anchoring system secures the array to shore, distributes loads along large portions of the array, and prevents loads from being concentrated in small regions of the array, thereby preventing damage from environmental forces typically encountered in outdoor marine environments.

### CROSS REFERENCE TO RELATED APPLICATIONS

The present application is a continuation-in-part of U.S. Utility patent application Ser. No. 11/861,226, filed Sep. 25, 2007 (Sep. 25, 2007), which is a continuation-in-part of U.S. patent application Ser. No. 11/264,285, filed Oct. 31, 2005 (Oct. 31, 2005), which claims the benefit of U.S. Provisional Patent Application Ser. No. 60/623,328, filed Oct. 29, 2004 (Oct. 29, 2004); and also claims the benefit of U.S. Provisional Patent Application Ser. No. 61/492,224 filed Jun. 1, 2011 (Jun. 1, 2011.)

### STATEMENT REGARDING FEDERALLY SPONSORED RESEARCH OR DEVELOPMENT

Not applicable.

### REFERENCE TO A MICROFICHE APPENDIX

Not applicable.

### TECHNICAL FIELD

The present invention relates generally to photovoltaic power systems, and more particularly to support structures for solar photovoltaic collector panels, and still more particularly to a modular floating support structure for a solar panel array.

### BACKGROUND INFORMATION AND DISCUSSION OF RELATED ART

With a few exceptions, solar panel support structures are almost invariably adapted for installation of solar panels or solar collectors on the ground or on a rooftop. Notable exceptions include support frameworks for mounting solar panels on vehicles and boats, and more exotic uses may even call for an installation with no support framework, such as with small “glue on/screw on” thin solar panels for use in extreme environments.

Rooftop solar arrays require the modification of the rooftop structure, can be dangerous and difficult to work on, and provide only a limited footprint. On the other hand, land (the ground itself) is increasingly expensive and may be usefully employed for a number of purposes other than solar array installation. Additionally, the amount of land required for a solar array that generates a productive amount of electrical power can be considerable. Accordingly, because bodies of water comprise two thirds of the surface area of the earth, and because many large areas of water surfaces have no critical uses that cannot be provided for elsewhere, it may be desirable to dedicate large surface areas of water to the collection of solar energy and the conversion of solar energy to electricity.

Systems and apparatus specifically adapted for floating a large array of solar panels are developing, but they are relatively new and thus currently present several as yet unsolved problems. Few practical and economically feasible systems have been disclosed; fewer still have reached the market place. A simple system known to the present inventors is shown in Japanese Patent Appl. Pub. No. JP-2001-189486, by Kusakabe et al. This application shows a metal framework of elongate L- or U-shaped channels mounted on cylindrical drum floatation elements. The frame elements provide a generally horizontal base on which solar panels are mounted.

However, neither the foregoing Japanese patent application, nor any other known land based systems, provide certain critical solutions for assembling and deploying large scale arrays on water, nor does any known art teach comprehensive mooring and anchoring solutions for placement of large scale arrays on water. The systems now known require the connection and assembly of array units on the water, and mooring systems leave large scale arrays vulnerable to damage from wind and wave action.

### BRIEF SUMMARY OF THE INVENTION

The present invention is a floating support structure for solar panels and/or concentration collectors. The invention provides the means to mount an array of solar panels or other PV or thermal elements on modular floating platforms joined together to form an array. Such an array may include only a few array modules, or it may include many hundreds or even thousands of modules. The invention includes a system for assembling and connecting floating support modules on land for deployment onto water using a crane or roller conveyor system. The invention further includes a mooring and anchoring system for connecting an array to shore in manner that prevents overstress of the structural components comprising the array field.

In the most summary terms, the inventive system includes floatation elements (“floats”), a solar module support structure, solar modules of one kind or another, wireways, walkways, and connectors and fasteners. The system is preferably assembled on land in modular sections, each of which supports at least one solar PV panel, but preferably supporting 4-12 panels or solar collectors of suitable size. The array module is the fundamental unit or building block of an array and they can be combined on land into units for collective deployment, or launch. The unit size can be scaled up or down and the deployment onto water can be can be accomplished using a crane or conveyor system. In the alternative, array modules can simply be assembled on water, though for large arrays, land assembly is the preferred method.

Each array module includes floatation disposed on at least one side (depending on the position of the module in the array field). When integrated into an array, the connected modules create a monolithic structure comprising contiguous modules that define walkways, wireways and panel/collector supports. The system may have rigid connections between sections although the compliance of the materials may flex to accommodate movements caused by waves and wind. The system preferably includes hinges or flexures between array modules and module sections. The system is designed to support winds up to a least 90 mph and wave forces generated by a minimum of 12 inch waves.

The floatation elements of the present invention may be provided by a number of suitable products. Such options include standard (off-the-shelf) or custom dock floats consisting of expanded polystyrene (EPS) foam filled, polyethylene dock floats, either thermoformed, rotomolded or blow molded, or similar materials. Alternatively, hollowed vessels such as rotomolded plastic volumes or other floating devices can be employed.

The support structure, the module connections, and the mooring and anchoring system for the array field are collectively designed to withstand the compounded forces of an entire floating array during a minimum of 90 mph winds. The support structure can either have hinged framework connections throughout the array or can comprise a monolithic rigid structure. The materials may flex to accommodate movement in the system. Frame members may be fabricated from high density polyethylene (HDPE) or similar structural foam molded (injection molded) “truss” or structural beam configurations to support the required loads. Steel, aluminum or similar metal truss, sheet or formed structures may also be employed to comprise a rigid structure, as may steel, aluminum or similar metal members welded or mechanically fastened. The use of lightweight composite materials is also contemplated.

The completed structure of an assembled floating solar array field is a hybrid of diagonal (braced) and Vierendeel (flexural) trusses. Diagonals are used to couple the east-west members at each pontoon (floatation element) together to form east-west “beams,” and flexural components of the Vierendeel consist of those east-west beams and the north-south beams. These components provide global array field stability by transferring the wind forces from the array field to strategic mooring support points.

When the frame members are connected, secondary walkways are defined in the area between connected adjoining north-south modules. The walkways are thus generally oriented in an east-west direction. These E-W walkways are principally intended for construction, operations, and maintenance personnel and are coincident with the top surface of the floatation devices.

A main wireway/walkway preferably runs in a north-south (N-S) direction, but it can also run E-W. The N-S wireway/walkway is likewise designed for construction, operations and maintenance personnel, but it also includes an elevated housing for electrical equipment and wires, including combiner boxes and disconnects. Electrical wires run through the housing generally along the surface, along the side, or in wireways on top of the walkway surface. Wires may emerge from the housing at any point along the walkway or at one or more of its ends, and it may then be submerged before being directed to shore. The wireway may include wire dividers to separate the wires in order to promote heat dissipation and to avoid overheating.

The mooring and anchoring configuration used in the present invention is specific to site conditions and array layout. However, in all instances the mooring and anchoring design is configured to produce equal force resistance to each array support point through the use of a continuous and running mooring line. This design feature is found in all of the inventive mooring arrangements.

The inventive system may employ either above water or below water mooring elements, or both. Each approach provide uniform force resistance for array global stability. An above water system comprises the structure that forms the array field (consisting of the east-west, north south, and bracing steel components), a continuous mooring line that runs through pulleys disposed on array mooring supports and at the ends of anchored mooring lines, the latter which are made of galvanized wire strop that terminates at a ground anchor. As will be appreciated, suitable materials for the moorings lines are myriad and varied and include, without limitation, polyester, para-aramid fiber, galvanized or stainless steel cable, and so forth.

While an above water mooring system is preferred for many reasons, a below water system is nonetheless possible and practicable. A below water mooring system is similar to an above water system except that the continuous mooring line is routed through below water blocks attached to anchored mooring lines, which in turn are anchored by either concrete deadman or soil anchors driven into the submerged bed.

Maintaining global stability of the entire array field requires preventing overstress of the structural components that make up the array field. To achieve this, the mooring system for the inventive floating support system is designed to distribute the forces equally at mooring support points of the array. The system addresses the problem encountered when running individual lines directly from shore to the array, which is that the differential in stiffness of any two lines is a function of several factors: (1) anchorage take up (amount of anchorage deflection to engage resistance); (2) initial line slackness; (3) line creep—i.e., the sustained load on a line will increase with the length of the line; (4) water level variations—as the water level decreases or rises, the lines increases in length depending on the mooring system; (5) elastic shortening—each line will vary in length, so the line stiffness will vary; (6) array rotation caused by winds or currents.

These factors suggest that loads can be transferred to anchor points through fewer lines, which in turn can cause stress concentrations in the structural members in the array field. The inventive system solves this problem by employing a continuous line and running pulleys, which results in a constant tension force in the continuous mooring line that attaches to the array field. The force imposed to the array to resist the lateral wind loads is therefore constant in magnitude but varies in direction based on the mooring line geometry. The geometry is then controlled in the design process to balance loads in the east-west and north-south members.

More specifically, a typical array is designed to be supported at the north and south ends with the constant tension mooring layout with four continuous rope segments, one for each quadrant of the array. The mooring lines are splayed radially to provide resistance for loading in the east-west direction and to provide torsional stability of the array. For loading in the north-south direction, the forces are transmitted equally through the mooring lines on the windward side to the anchors. For loading in the east-west direction, the forces are transmitted equally through the mooring lines along the north and south sides of the array at the windward side of the array. For loading at an angle to the orthogonal directions, the forces are transmitted through a combination of the above scenarios. Any global rotation of the array is resisted by diagonally opposite corners. Thus, as the array rotates, the resisting lines go taut in an attempt to lengthen, but they are prevented from doing so because of the radial geometry. Therefore, they resist the global rotation with an equal force distribution in all the lines.

The continuous (running) mooring line used in the inventive system generates a force limited to what the structural components of the array can withstand. This force limit depends on site-specific design parameters, size of array, and mooring layout. To ensure structural soundness, the anchored mooring line and its anchor are selected to withstand twice the force generated in the continuous mooring line.

When the mooring system is positioned above the water surface, the continuous mooring line attachment of the inventive system uses pulleys at the anchored mooring line end, which is kept out of the water by means of a buoy. This prevents marine organisms from growing and obstructing free operation of the pulley and provides ease of visual observation for maintenance. The pulley is free to rise upward except for the nominal weight attached through the mooring sleeve of the buoy. This occurs when the water level is low and the wind force is sufficient and oriented in direction to engage the mooring line.

The mooring and anchoring system also includes anchor elements. The anchored mooring line that attaches to the continuous mooring line can be anchored in myriad ways, but falling generally into two broad types: (1) a continuous mooring line can be attached to a series of lines directly anchored to the ground through either a concrete deadman, ground anchor, or a pile (cast in place, driven, torqued, etc.), and preferably consist of galvanized steel strands; or (2) a catenary mooring line can be anchored at each end by similar methods above in an east-west configuration and spans across the water, and affords discrete points to attach the anchored mooring line to the continuous mooring line.

When a portion of the mooring system is positioned below the water surface, it includes moving parts in a below water environment. Problems of corrosion and abrasion are addressed through the selection of materials. The kinematics (viz., continuous mooring line running through pulley) and design approach are similar to the above-water mooring application except that in the event of water level rising and full wind load on the array, the array tends to be pulled down into the water at the array support points. The geometric design therefore requires the angle from horizontal to the mooring lines to be less than for the above-water condition.

On occasion, the inventive floating system for a solar panel array will be installed on a body of water having a variable water level. As the water level changes, the array's vertical position relative to the ground anchor points changes as well. In this environment, the array is installed in relation to the potential maximum and minimum water elevations. The mooring lines are pre-tensioned and released a fixed length at the time of installation, and if required during the maintenance period, to afford the relative vertical movement the array may go through during its design life.

From the foregoing, it will be seen that it is a primary object of the present invention to provide a new and improved modular floating support structure for a solar panel array.

A further object or feature of the present invention is a new and improved floating structure for a solar panel array that permits solar panels to be positioned for optimal solar energy collection while afloat.

An even further object of the present invention is to provide a novel floating structure for a solar panel array that is lightweight and easily transported to and assembled at or near an installation site, either on dry land or on the water.

Another object of the present invention is to provide an assembly system that enables land-based assembly of modular floating units and later deployment onto water of large blocks of pre-assembled and connected units.

Yet another object of the present invention is to provide a mooring system for the inventive floating solar panel array that will prevent overstress of the structural components that constitute the array field.

Still another object is to provide a mooring system for the inventive floating solar panel array that allows lateral movement and rotation in predetermined amounts so as to prevent overstress of the array while also allowing slight adjustments and a reorientation of the mounted panels.

Another object is to provide a floating support system for a solar panel array that can be deployed on small and large bodies of water, such as agricultural reservoirs, water district retention ponds, large reservoirs, lakes, ponds, and the like.

Yet another object is to provide a floating solar panel support system that has minimum volume for shipping.

These and other objects and advantages are achieved by the support structure, the assembly system, the deployment system, and the mooring and anchoring system of the inventive floating solar panel array of the present invention.

The foregoing comprises the broad outlines of the more important features of the invention to facilitate a better understanding of the detailed description that follows. Additional objects, advantages and novel features of the invention will be set forth in part in the description as follows, and in part will become apparent to those skilled in the art upon examination of the following. Furthermore, such objects, advantages and features may be learned by practice of the invention, or may be realized and attained by means of the instrumentalities and combinations particularly pointed out in the appended claims. As will be appreciated, the structural and operational elements of the inventive system and apparatus are capable of modification in various obvious respects without departing from the spirit of the invention. Accordingly, the drawings and description of the preferred embodiments are to be regarded as illustrative in nature, and not as restrictive.

### BRIEF DESCRIPTION OF THE SEVERAL VIEWS OF THE DRAWINGS

The invention will be better understood and objects other than those set forth above will become apparent when consideration is given to the following detailed description thereof. Such description makes reference to the annexed drawings wherein:

FIG. 1 is a perspective view of the modular floating support structure of the present invention, shown supporting two solar panels;

FIG. 2 is a front view in elevation thereof;

FIG. 3 is a rear view in elevation thereof;

FIG. 4 is a side view in elevation thereof;

FIG. 5 is a side view in elevation of a plurality of the modular floating support structures showing how such structures may be connected and deployed in a floating solar panel array;

FIG. 5A is a perspective view showing a bar with carabineers disposed at its ends as used to connect adjacent modules at their respective sides;

FIG. 6 is a top view showing a plurality of the inventive modular support structures connected in an array;

FIG. 7 is a side view in elevation of a second preferred embodiment of the present invention, showing an individual floatation element and a solar panel mounted thereto;

FIG. 7A is a rear view thereof;

FIG. 7B is a side view in elevation of a solar panel array mounted on a plurality of the floatation and support elements shown in FIGS. 7 and 7A;

FIG. 8 is a top plan view thereof, the floatation elements being shown with phantom lines;

FIG. 9 is a side view in elevation of the floatation element of the second preferred embodiment showing the structural components in phantom;

FIG. 10 is an end view in elevation of the exterior interior portion of the end cap for the floatation element of the second preferred embodiment, shown along line 10-10 of FIG. 11;

FIG. 11 is a cross-sectional side view in elevation showing the end cap, exterior and interior tubes, and mounting apertures of the floatation element, the view taken along section line 11-11 of FIG. 10;

FIG. 12 is an end view in elevation of the interior side of the floatation element end cap viewed from line 12-12 of FIG. 13;

FIG. 13 is a cross-sectional side view in elevation of the end cap and tube elements taken along section line 13-13 of FIG. 12;

FIG. 14 is an upper left front perspective view showing a third preferred embodiment of the modular floating support structure of the present invention, shown supporting an array of solar panels;

FIG. 15 is an upper left perspective of the modular floating support structure and solar panels as shown in FIG. 14;

FIG. 16 is a top plan view of the inventive apparatus supporting a large array of solar panels;

FIG. 17A is a cross-sectional side view in elevation of the inventive apparatus taken along section line 17A-17A of FIG. 16;

FIG. 17B is a cross-sectional side view in elevation of the inventive apparatus taken along section line 17B-17B of FIG. 16;

FIG. 18 is an upper front left perspective view showing detail of the terminal end of the lateral gangway joining elements of the modular floating support structure of the present invention, taken along detail line 18 of FIG. 14;

FIG. 19 is an upper rear left perspective view of the other terminal end of the lateral gangway, taken along detail line 19 of FIG. 15;

FIG. 20 is an upper perspective view of an alternative floatation element for the inventive apparatus;

FIG. 21 is an exploded view showing the floatation element of FIG. 20;

FIG. 22 is a cross-sectional end view in elevation taken along section line 22-22 of FIG. 20;

FIG. 23 is a cross-sectional side view in elevation showing a fourth preferred embodiment of the floatation element of the present invention;

FIG. 23 is a cross-sectional side view in elevation of a fifth preferred embodiment of the floatation element;

FIG. 24 is a schematic upper front perspective view of a floating solar panel array according to the present invention, showing the assembled array, the north-south wire wireway/walkway, and the mooring system connections to the array field;

FIG. 24A is a schematic upper front right perspective view of a module of the inventive system;

FIG. 25 is an exploded upper left front perspective view showing the floatation elements and east-west frame members;

FIG. 26 is an upper left front perspective view showing the floatation elements joined by the east-west frame members with cross braces installed;

FIG. 27 is an exploded upper left front perspective view of north-south frame members;

FIG. 28A is an upper left front perspective view showing the panel mounting structure installed on the floatation elements and north-south frame members;

FIG. 28B is an upper left rear perspective view thereof;

FIG. 29 is an upper left front perspective view showing four panels mounted on the floatation and support structure;

FIG. 30 is an upper left front perspective view showing the east-west frame members of adjoining modules connected by the splice member of the present invention;

FIG. 31A-D are upper left front perspective views showing use of the splice to couple and connected east-west frame members;

FIG. 32 is an upper left front perspective view showing the hinged connection between north-south frame members in adjoining modules;

FIG. 33A is an upper front left perspective view showing support elements for a north-south wireway/walkway;

FIG. 33B is an upper rear perspective view thereof;

FIG. 33C is an upper front left perspective view showing the north-south wireway/walkway with the wireway covered;

FIGS. 34A-34D are schematic top plan views showing assembly of the modular elements, first singularly in the east-west direction, then in groups of three in the north-south direction, and then completing the field or partial field by adding an E-W line of floatation elements to the northernmost set of array modules;

FIG. 35 is a schematic top plan view showing two 18-module arrays positioned for connection to another through a wireway/walkway which will be interposed between;

FIG. 36 shows the array fields of FIG. 35 joined to a north-south wireway/walkway;

FIGS. 37A-37D are highly schematic side views in elevation showing how the modules can be assembled (cf, FIGS. 34A-D) in rows on the bank or berm surrounding a body of water and then deployed or launched in coupled groups of modules;

FIG. 38 is a schematic top plan view of the mooring approach used to stabilize and protect an array assembled from the floatation and support elements of the present invention;

FIG. 39 is a schematic top plan view showing an array field with medial N-S wireway/walkway and a mooring line attachment scheme;

FIG. 40 is an upper left perspective view showing a south interior mooring system connection using a terminal block (or pulley) for routing the continuous line to a terminal cleat;

FIG. 41 is an upper left perspective view showing a mooring line connection to an array at a medial pulley;

FIG. 42 is an upper left front perspective view showing a corner terminal mooring attachment using a shackle;

FIG. 43 is an upper left front perspective view showing a north interior mooring line connection using a pulley to route a continuous line to a terminal cleat under the walkway portion of a N-S wireway/walkway;

FIG. 44 shows a spherical mooring buoy employed to keep mooring lines out of the water so as to prevent damage, corrosion, and fouling of an intermediate pulley;

FIG. 45 is a highly schematic top plan view of the mooring approach of the present invention installed on a rectangular floating array;

FIG. 46 shows the response of the mooring system to lateral translation of the floating array in a westerly direction due, for instance, to wind; and

FIG. 47 shows the response of the same mooring system as the array is rotationally translated by a southeasterly wind.

### DETAILED DESCRIPTION OF THE INVENTION

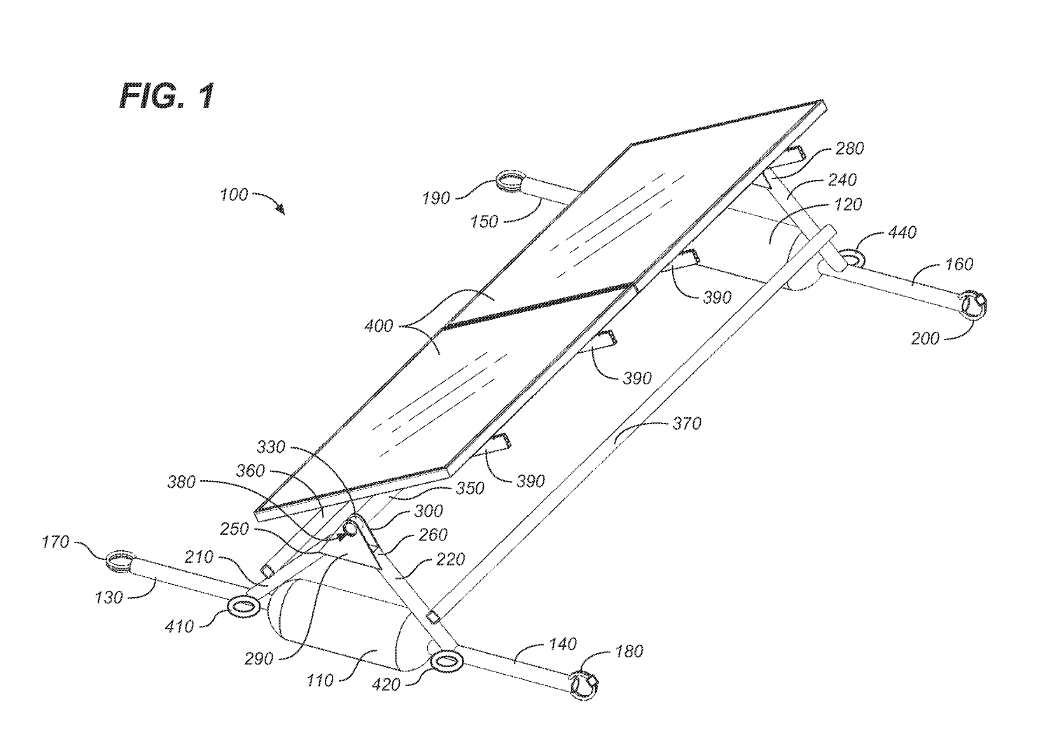

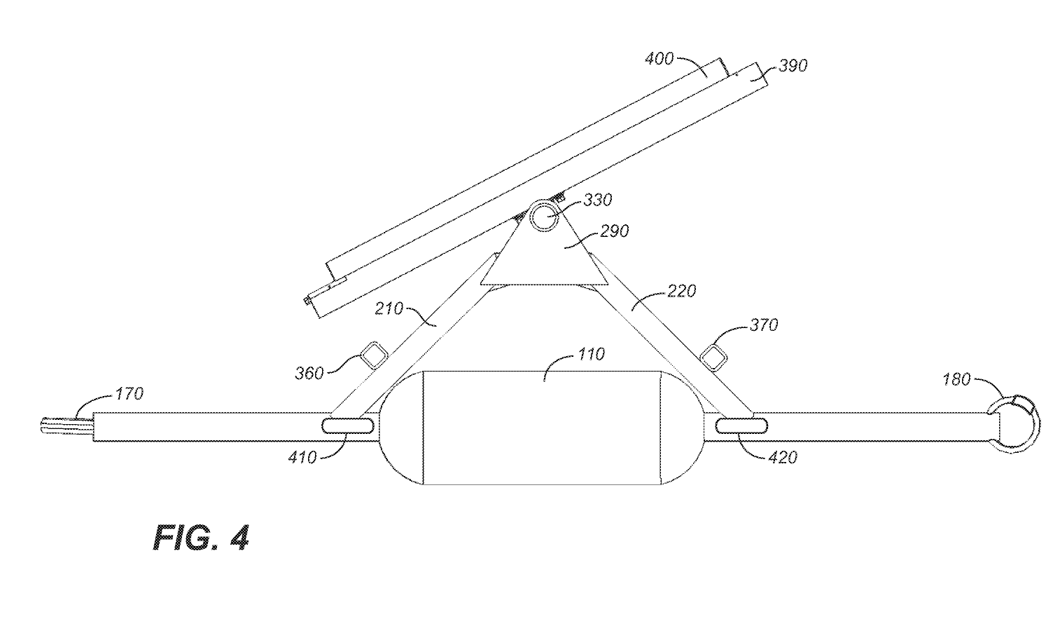

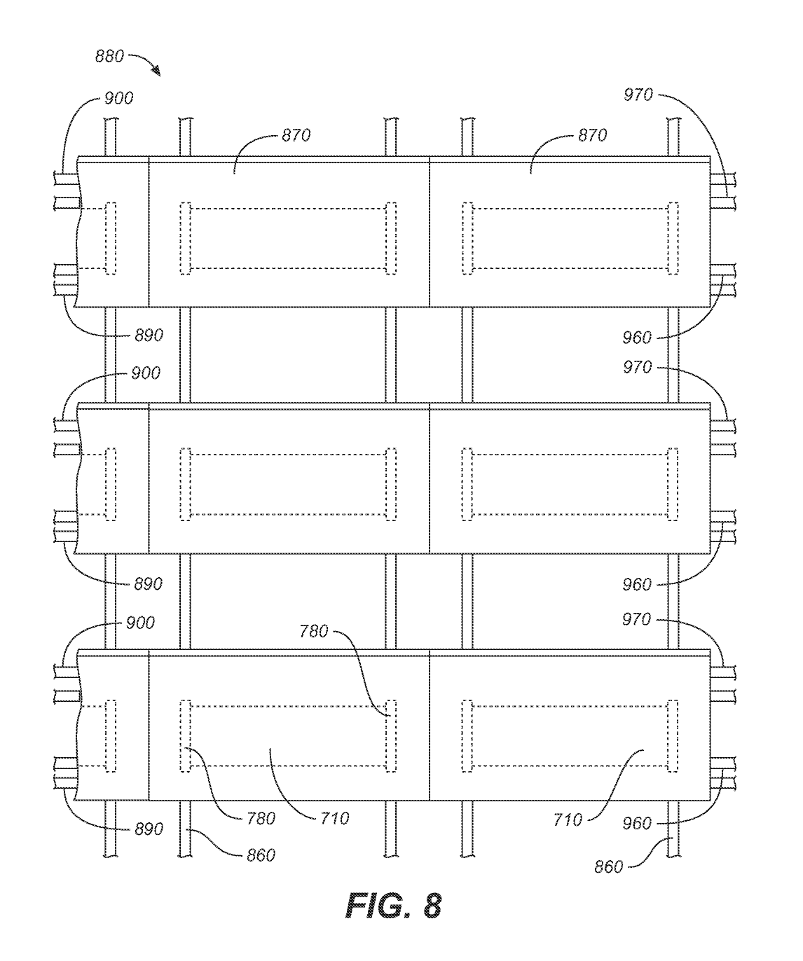

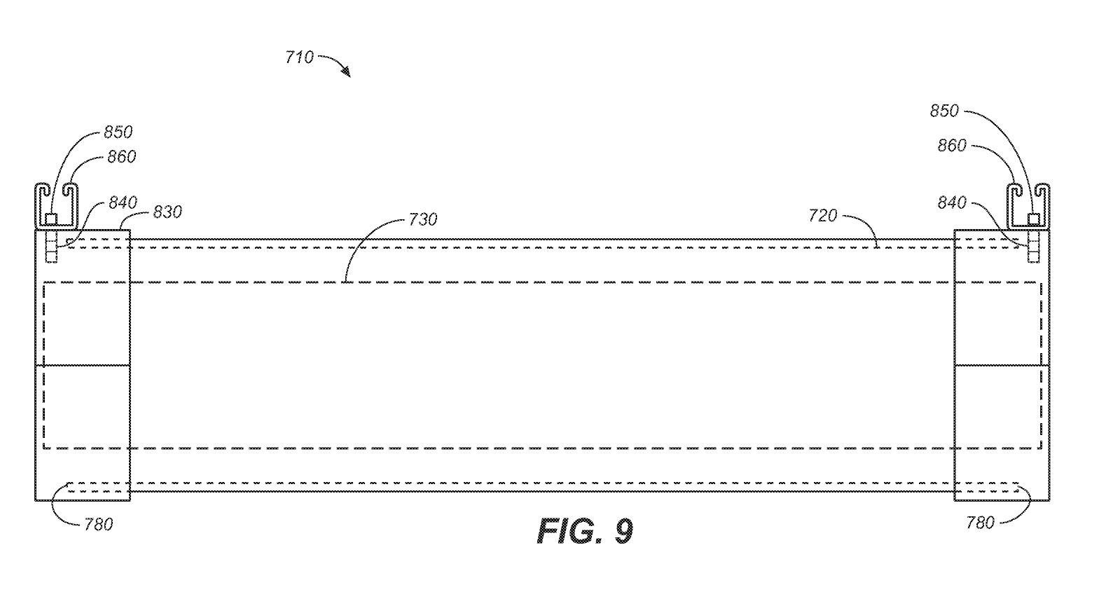

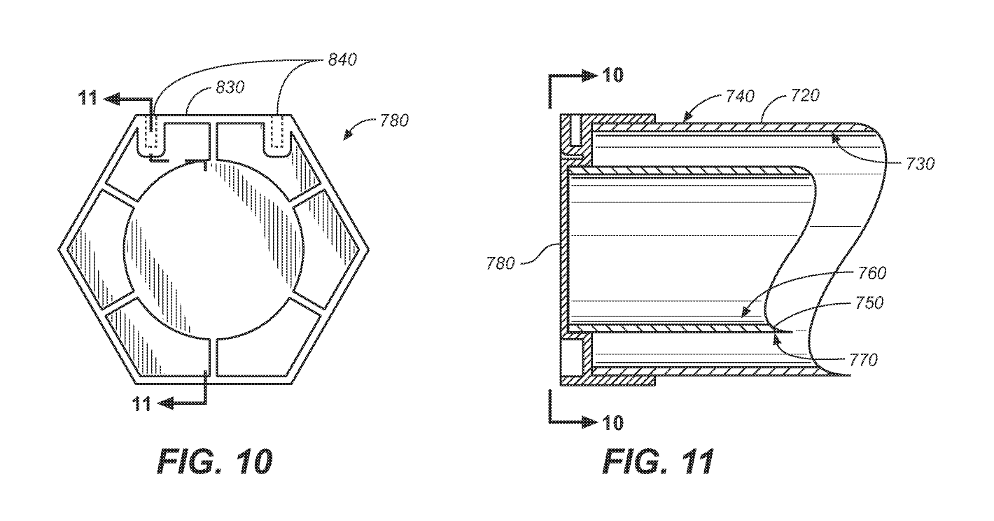

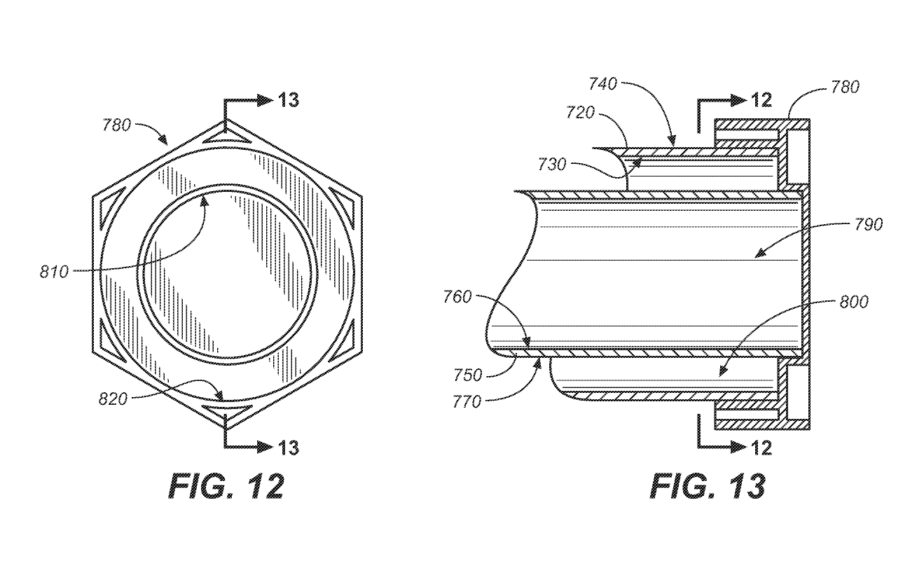

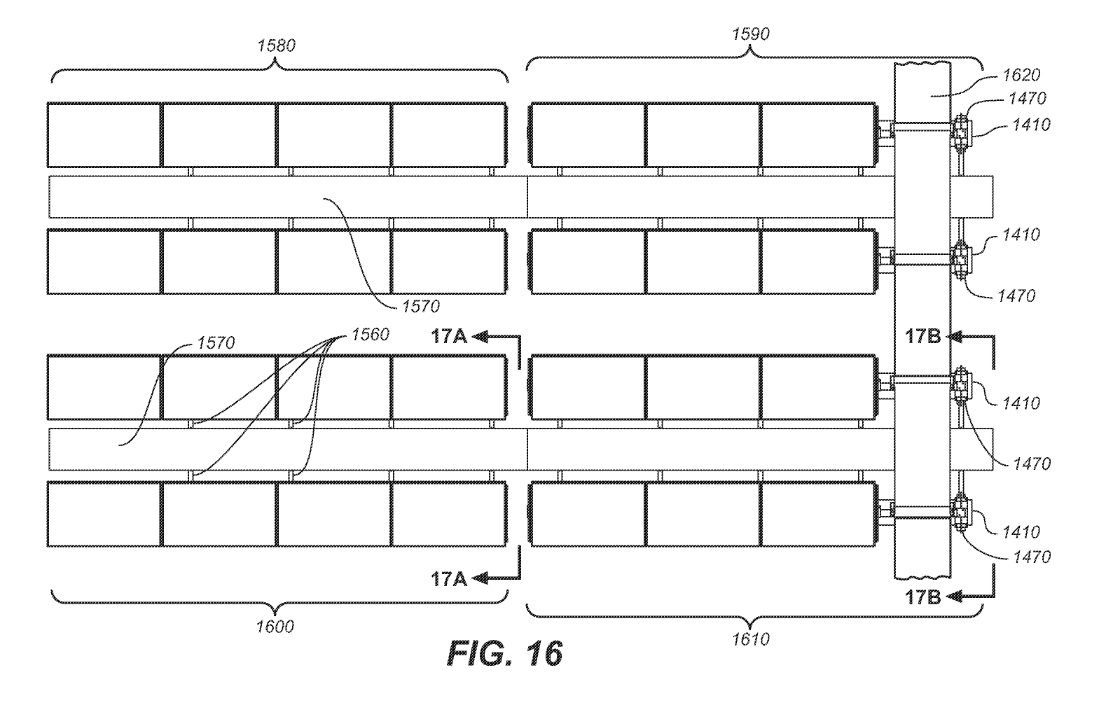

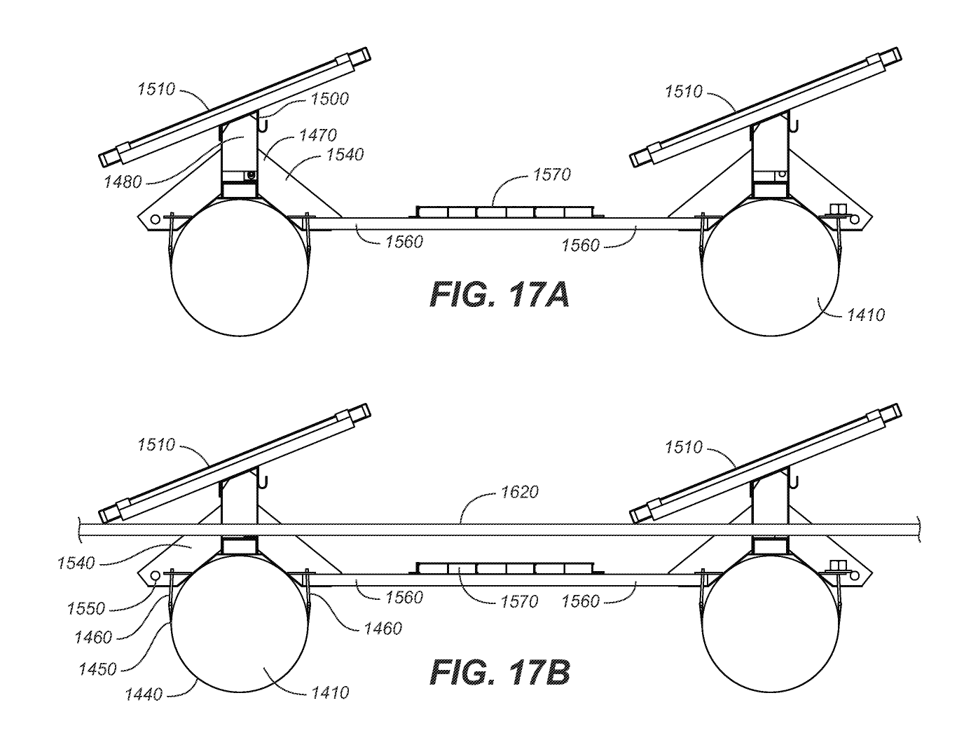

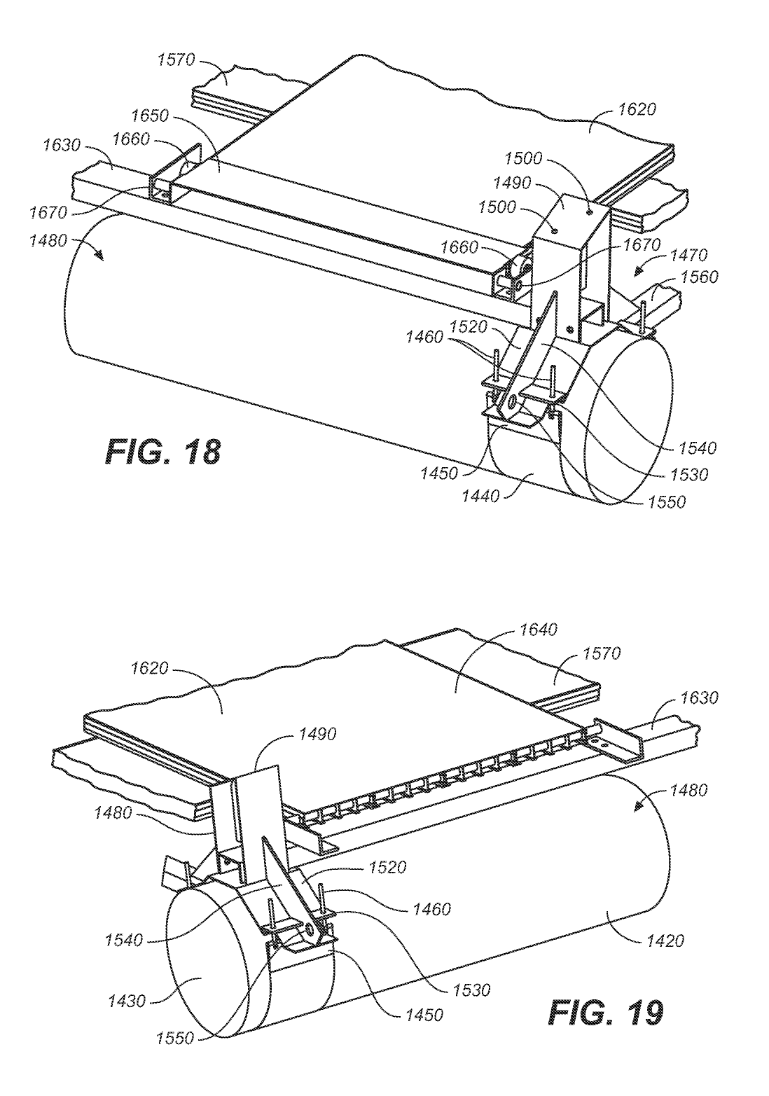

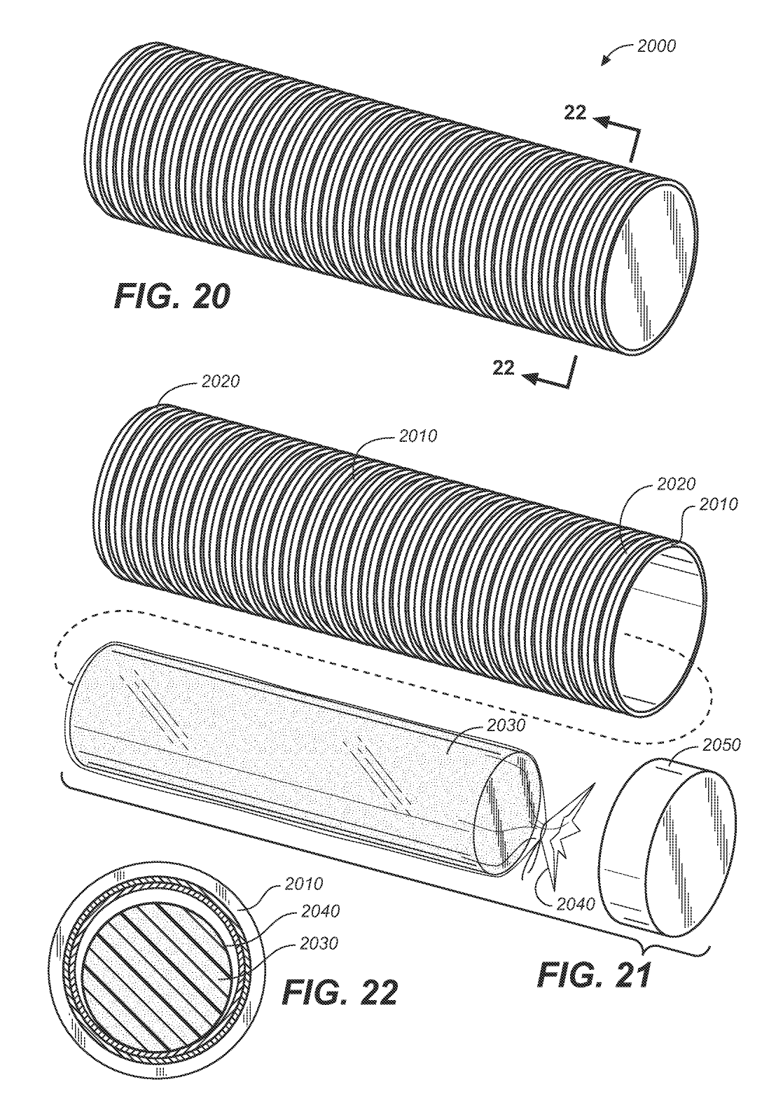

Referring to FIGS. 1 through 47, wherein like reference numerals refer to like components in the various views, there is illustrated therein a new and improved modular floating support structure for a solar panel array. Referring first to FIGS. 1-6, there is shown a first preferred embodiment of the inventive structure, which is generally denominated 100 herein.

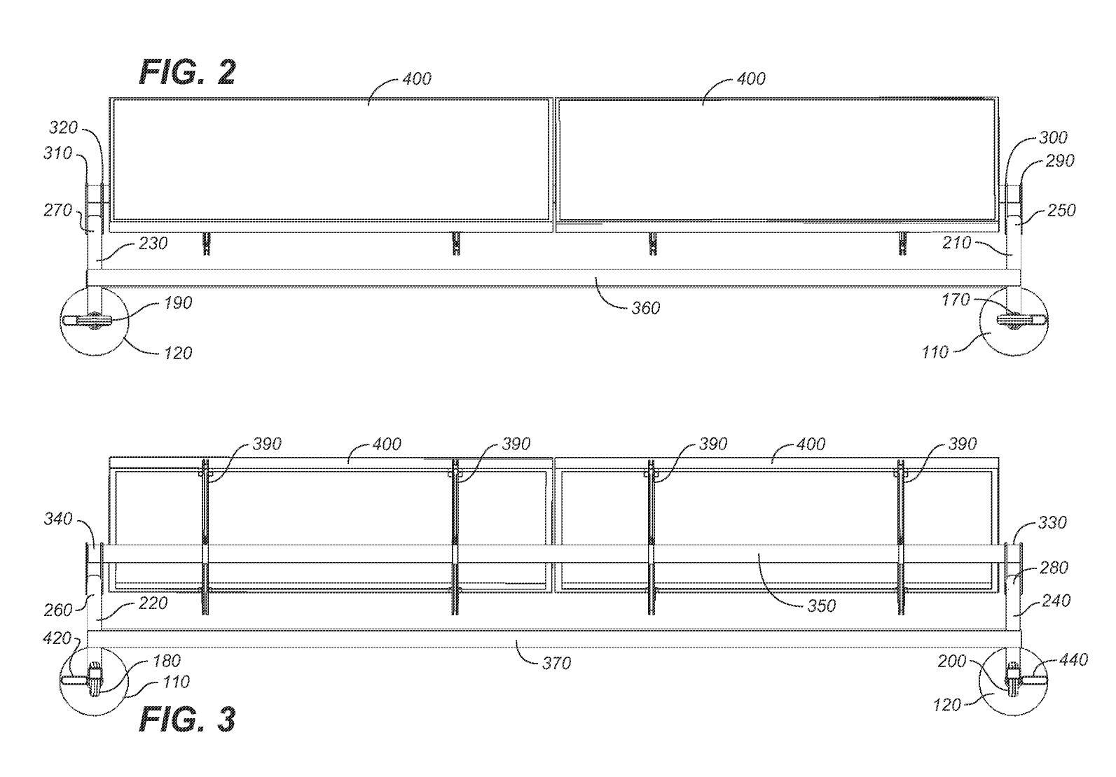

FIG. 1 is a perspective view of the first preferred embodiment of the modular support structure, while FIGS. 2, 3, and 4 are, respectively, front, back, and side elevation views of the module of FIG. 1. Collectively, these views show that this basic modular component of a floating array comprises first and second elongate flotation elements 110, 120, preferably substantially cylindrical pontoons, each having connector tubes 130, 140, and 150, 160, extending longitudinally from each end of the pontoons. Preferably the connector tubes are round in cross section, and their respective distal ends include front and rear connection means, preferably connector rings, 170, 190, and 180, 200, respectively. The front connector rings 170, 190 are disposed generally perpendicular to the rear connector rings 180, 200, and either the front or rear connector rings or both are provided with a hinge element that allows the rings to capture rings in an adjacent module, in the manner of a tubular carabineer. Effectively, then, one set of connector rings comprises rigid connector rings, while the complementary set of connector rings comprises carabineers that attach to the rigid connector rings. As with carabineers, it is well known to provide locking means to prevent the hinge element in the carabineer from inadvertently opening. Such structures considered obvious design choices and are contemplated within the scope of the present invention.

Straddling the ends of each flotation element are angled upright supports, 210, 220, and 230, 240, glued, welded, bolted, or otherwise affixed at their lower ends to the connector tubes extending longitudinally from the flotation element, or to the flotation elements themselves, and which angle inwardly toward one another to join or substantially join at their respective upper ends, 250, 260, and 270, 280. The angled uprights are preferably fabricated from square tubing. The manufacturing means may be adapted to the anticipated installation, as welding or gluing may provide a sturdier structure with greater durability, but assembly with nuts and bolts may allow for easy transportation for assembly at an installation site.

Spaced apart parallel plates 290/300, and 310/320, may be glued, welded, bolted, or otherwise rigidly affixed to the opposite sides of the uprights at or near the junction of the upper ends of the angled uprights to provide increased structural integrity. Additionally, the plates may be provided with holes in which to journal the ends 330, 340 of a rotatable panel frame mounting tube 350. Two or more additional transverse tubes 360, 370, may be disposed between, and connected to, the angled uprights, so as to make a generally rigid framework structure. Adjustment/locking means 380 may be provided to permit selective release, rotation, and re-locking of the mounting tube. A number of suitable devices can be provided, including hole and nipple assemblies, pawl and ratchet, locking collar and ring, and the like. The drawings show a pawl and ratchet assembly as an illustrative mechanism.

The rotatable panel frame mounting tube can be provided with a plurality of support rails 390 on which to fasten and secure one or more solar photovoltaic panels 400.

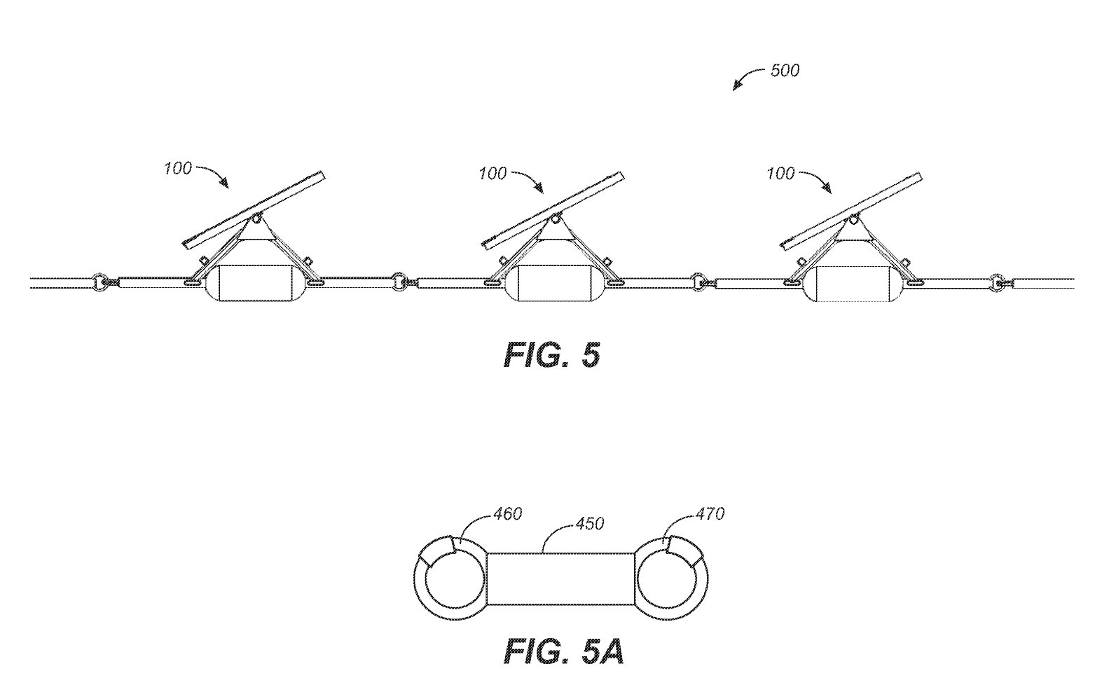

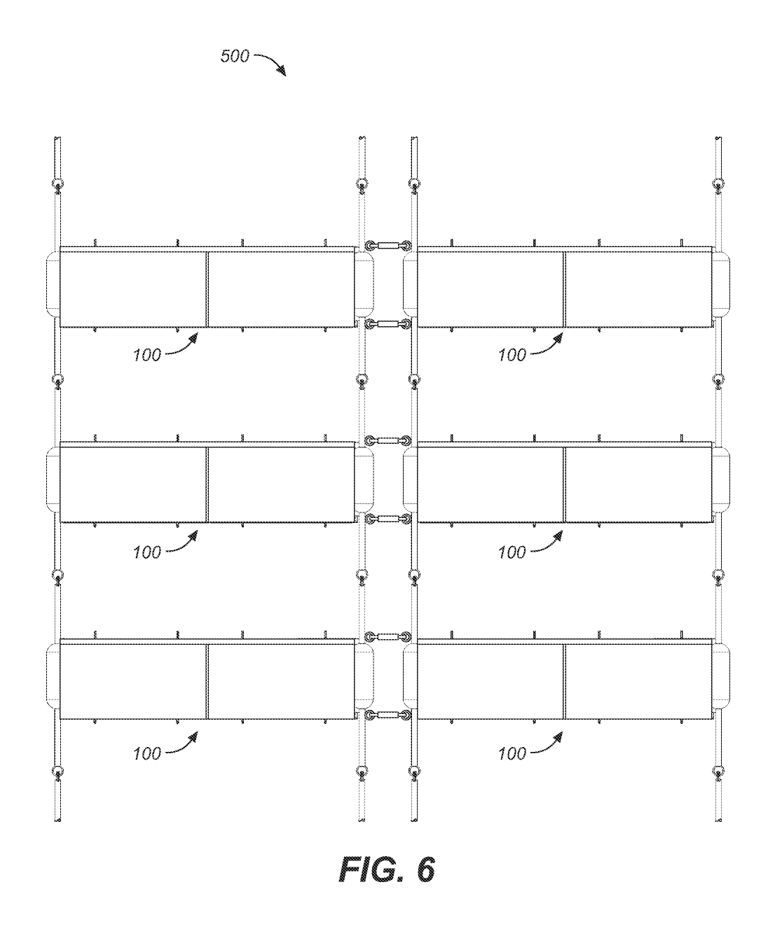

The module framework may also be provided with side connector rings 410, 420, 430, 440, disposed along each of the sides of the support structure. While only one side connector ring need be provided for each side of the support structure, and may be positioned anywhere along the length of the flotation element or connector tubes, it is preferable to have two side connector rings, one each extending outwardly from a each front and rear connector tube. Referring now to FIG. 5A, side connector bars 450, having hinged carabineers connector rings 460, 470 at each end may then be provided as means for joining the sides of adjacent support modules in a floating solar panel array 500 (see FIGS. 5 and 6). As an alternative, a side connector bar may be provided for installation between the front or rear connector ring of an adjoining support structure, so that no additional rings need be provided to ensure that the spacing between floating modules is fixed.

FIGS. 5 and 6 show the modules of FIGS. 1-4 connected with the above-described connector rings and side connector bars to form a floating solar panel array 500. The support modules are preferably spaced in accordance with ambient wave conditions of the body of water in which the installation will be deployed. Thus, the sizing and weight distribution of each module, and the spacing of modules relative to one another, can be tailored to minimize roll, pitch, yaw, heave, surge and sway under the wave conditions most likely to be encountered in the particular environment of use.

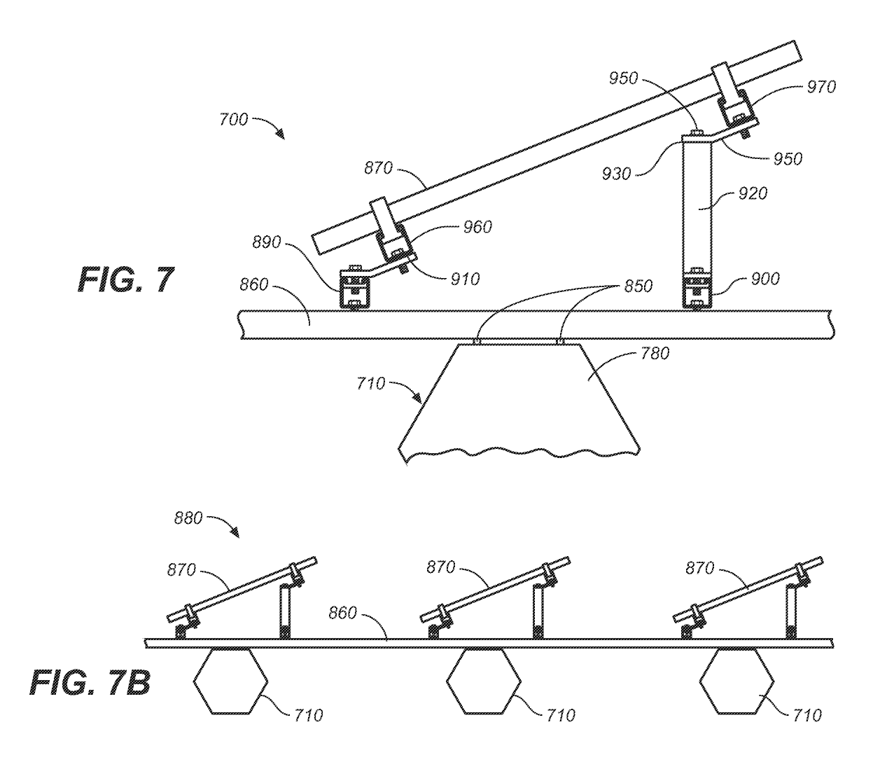

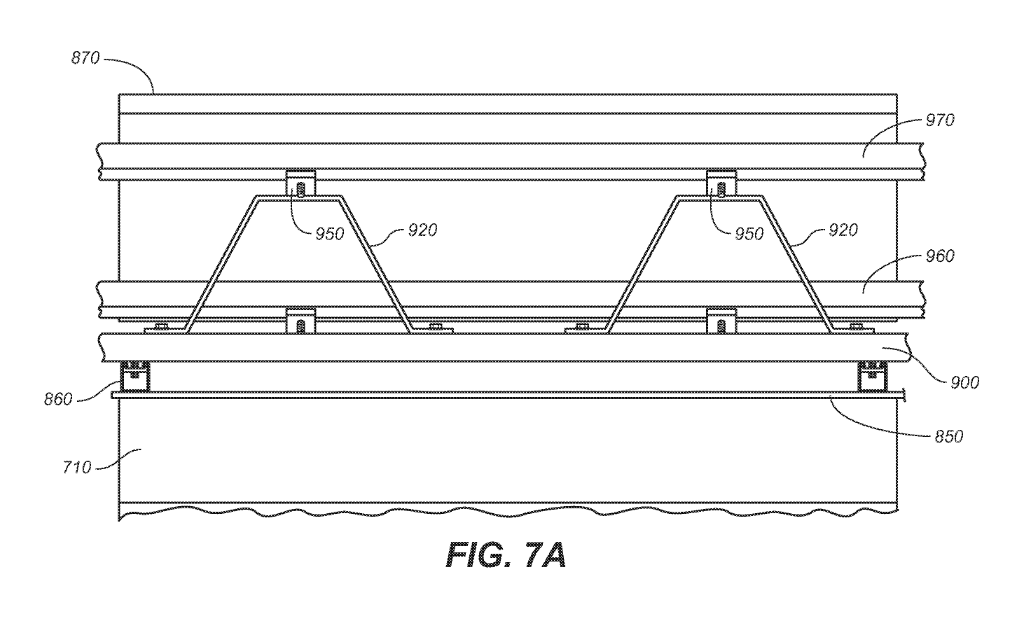

FIGS. 7-13 show a second preferred embodiment 700 of the modular floating support structure for a solar panel array of the present invention. In this alternative embodiment, the floatation elements 710 comprise an outer tube 720 having an interior wall 730 and an exterior surface 740, an inner tube 750 having an interior wall 760 and an exterior surface 770 spaced apart from the interior wall of the outer tube, and polygonal end caps 780 welded to the ends of the outer and inner tubes so as to create a watertight and airtight seal over first and second air chambers 790, 800.

The end caps 780 are preferably polygonal when viewed on end (see FIG. 7), and are conformed on an interior surface with an inner socket 810 which tightly fits over, captures, and retains an end of the inner tube 750 when welded, and an outer socket 820 which tightly fits over, captures, and retains an end of the outer tube 720 when welded. The top side 830 of the end caps essentially comprise a mounting platform which include apertures 840, preferably threaded, for accepting mounting bolts 850 to be employed in fastening the solar panel mounting structures.

The foundation of the mounting structures includes front and back lowermost structural channel 860 preferably aluminum extrusions, which are mounted on the top side of the floatation elements with mounting bolts 850 and span transversely across the top sides of the floatation elements to join each adjacent pair into a structural foundation for one or more solar panels 870 in a solar panel array 880.

The second elements in the mounting structure include front and rear longitudinal structural channels 890, 900, which are removably mounted onto the lowermost structural channels 860 in a generally perpendicular orientation. A front foot 910, preferably bent solid bar, is removably mounted on the front longitudinal structural channel 890. A back modified queen post truss 920, with or without interior vertical supports, and also preferably bent solid bar, is removably mounted on the rear longitudinal structural channel 900. The truss includes a horizontal keystone portion 930 having apertures (not shown) for passing bolts 940 to removably mount a rear foot 950, also preferably bent sold bar. Front and rear panel rails 960, 970, attached to and disposed on the underside of each of the solar panels, are attached to the front foot and rear foot, respectively.

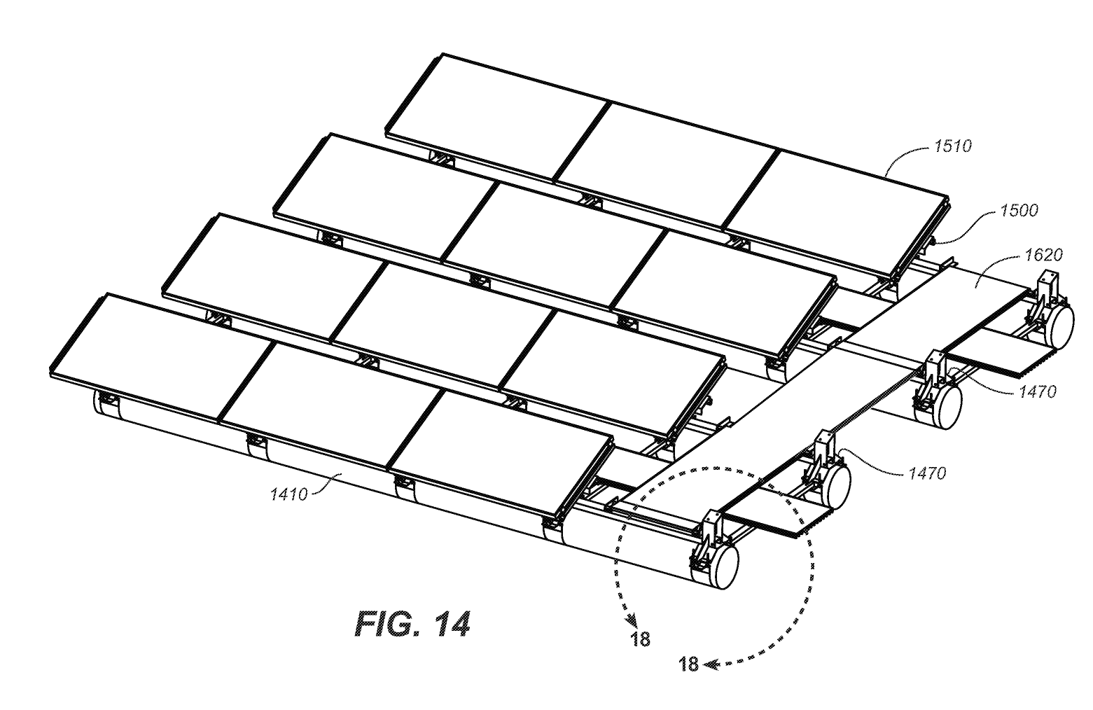

FIGS. 14-19 show a third preferred embodiment 1400 of the modular floating support structure for a solar panel array of the present invention. In this embodiment each of the floatation elements 1410 comprises a single substantially cylindrical tube or pipe 1420 covered with a welded cap 1430 at each end to form a watertight and airtight seal, as is well known in the art. The tubes are preferably fabricated from readily available PVC, HDPE, ABS, CPVC tubing material, though numerous other watertight materials would be perfectly suitable.

Mounting elements are disposed along the length of the floatation elements and proximate the ends. These structures include a slightly flexible metal band 1440 having ends 1450 with bolts 1460 extending therefrom. A mounting bracket 1470 is provided for placement over the top portion 1480 of the cylindrical pipe 1420. The mounting bracket 1470 includes a mounting post 1480 having an angled top 1490 with apertures for passing mounting bolts on which to connect panel rails 1500 disposed on the underside of solar panels 1510. The mounting brackets further include downwardly angling shoulders 1520 each having a horizontally extending tab 1530 with apertures for passing the bolts 1460 on the ends of band 1440. When bolts 1460 are tightened onto tabs 1530, the band and mounting bracket form a clamp over the cylindrical floatation element. The shoulders 1520 of the mounting bracket each also include an integral or welded reinforcement bar 1540 having an aperture 1550 for passing a fastener to join a connector bar 1560 between mounting brackets. The connector bars may be structural channel, solid bars, round or rectangular tubes, or other suitably strong elongate connector.

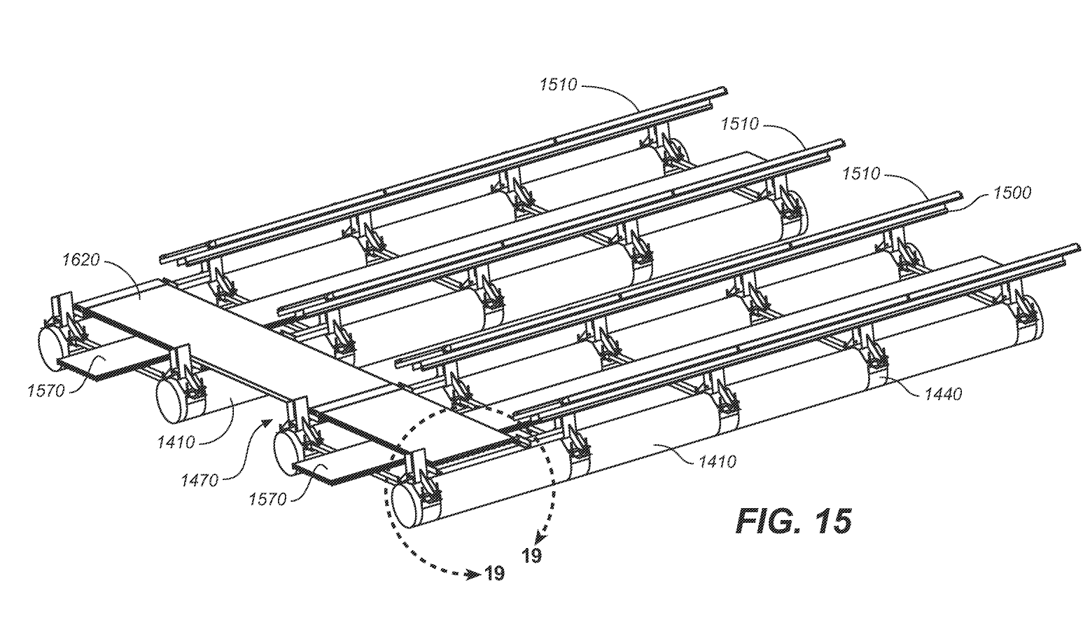

In the above-described and illustrated configuration, the floatation elements, mounting brackets, and connector bars provide a platform for mounting axially disposed gangways 1570, which are placed over the connector bars and provide access to the panels disposed along the length of the floatation elements, even when the apparatus is floating in deep water. Referring now to FIG. 15, it is seen that these elements combine to form discrete modular systems 1580, 1590, 1600, 1610 of the floating apparatus of the present invention. The gangways may be employed as connectors and when joined end-to-end with another gangway connect adjacent floating modules.

The third preferred embodiment of the inventive floating support structure for a solar panel array also includes a catwalk 1620 disposed over a plurality of floatation elements proximate their respective ends, or between any set of mounting brackets anywhere along the length of the floatation elements where solar panels are not mounted. The catwalk is disposed over mounting bars 1630, preferably extruded aluminum structural channel or steel channel, which extend between mounting brackets 1470. At a first end 1640 the catwalk is firmly attached to a mounting bar. A second end 1650 includes casters 1660 having a small amount of travel in a channel 1670 attached to a mounting bar. This provides some accommodation to movements caused by surface waves on the water. Either the catwalk or any one of the gangways may be joined to a dock to provide access from land to the floating array.

FIGS. 20-22 show a fourth alternative embodiment 2000 of the floatation element of the present invention. In this embodiment, the pontoon comprises doubled walled corrugated pipe having a channel or slot 2010 in each end 2020. A cylinder of foam 2030 covered by a watertight bag 2040 is inserted into the pipe and a cap 2050 placed on the end to form a watertight seal. Mounting apparatus described in connection with the third preferred embodiment may be employed for supporting a solar panel array.

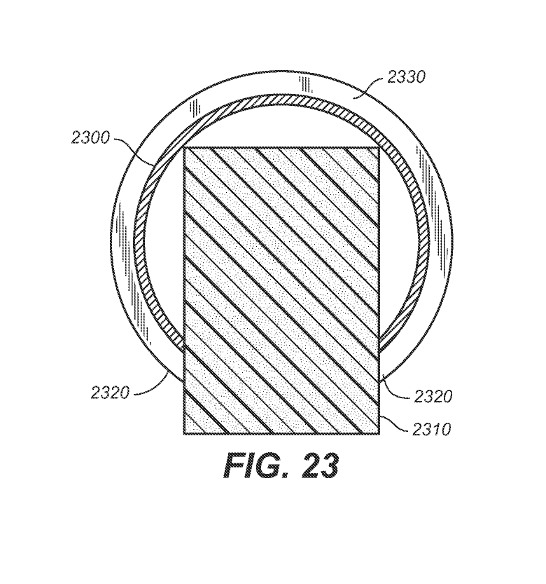

FIG. 23 shows a fifth preferred embodiment of the floatation element. In this embodiment, pipe 2300 is cut along its length to provide an axial opening into which a foam insert 2310 is wedged and captured by resilient ends 2320. Again, mounting apparatus as described in connection with the third preferred embodiment may be employed for supporting a solar panel array. Alternatively, mounting apparatus may be fastened (e.g., by bolts) directly to the upper portion 2330 of the cut pipe.

As will be appreciated by those with skill in the art, a number of suitable materials may be employed for the tubing and flotation elements of the support structure of the present invention for either of the preferred embodiments, including fibre glass, ABS, HDPE, PVC, CPVC, and the like, as well as composite materials, metals and metal alloys, and so forth. The various components need not be fabricated from the same material, and some combination of plastic, composite, and/or metal may be preferable.

The flotation element used in the present invention—i.e., the pontoon—is preferably sealed and may be left either with an unfilled void or it may be filled with polyethylene foam, polystyrene foam, or the like. FIGS. 13-15 show a possible floatation element configuration suitable for use in the present invention. This includes a corrugated cylindrical pipe, a foam insert having a watertight sealed plastic cover bag, and a cap at each end.

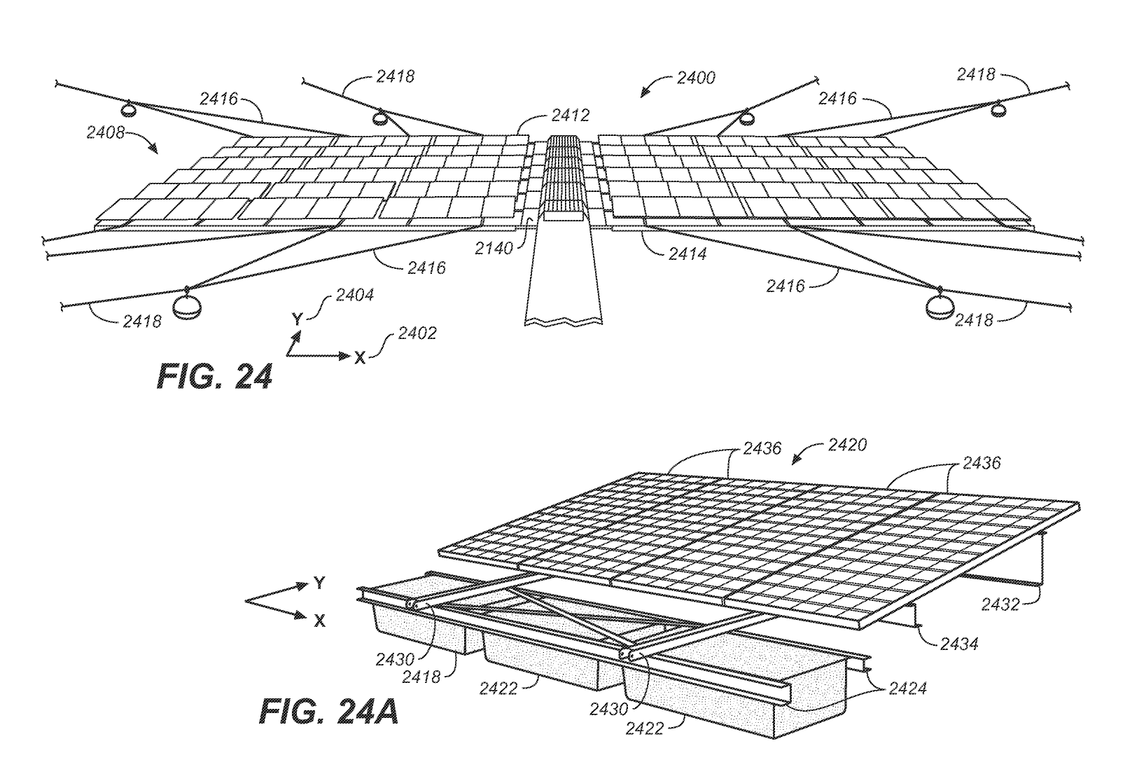

Referring next to FIGS. 24 through 47, there is shown still another embodiment of the inventive modular floating support structure for a solar panel array, generally denominated 2400 herein.

Referring first to FIG. 24, there is shown in schematic form a floating solar panel array according to the present invention. The floating array 2400 is oriented with panel rows aligned in a generally east-west (E-W) direction, corresponding to the X axis 2402 in this and other views. The N-S orientation generally corresponds to the Y axis 2404 shown in the various views. The assembled array thus includes an east portion 2406, a west portion 2408, a medial wireway/walkway 2410 disposed between the east and west portions, and a mooring system disposed on the north side 2412 and south side 2414 of the array, the mooring system including continuous mooring lines 2416 connected to the array field and static cables 2418 connected to in-ground or submerged anchors. (It will be appreciated that the choice of X and Y axes as reference lines in the views does not connote a rigid alignment of the axes with the cardinal directions. The selection is provided to facilitate an understanding of the views and is not in any way limiting.)

FIG. 24A shows an exemplary array module 2420 as used in the inventive system. In its most essential form, the array module includes floatation elements (herein “float” and/or “floats”) 2422, E-W frame members 2424 straddling the floats along their upper portions 2426 along their E-W sides, cross bracing 2428 disposed atop the E-W frame members, N-S frame members 2430 disposed atop the E-W frame members and extending across the top of the floats, a N panel support 2432, a south panel support 2434, and a plurality of solar panels 2436 mounted atop the panel supports.

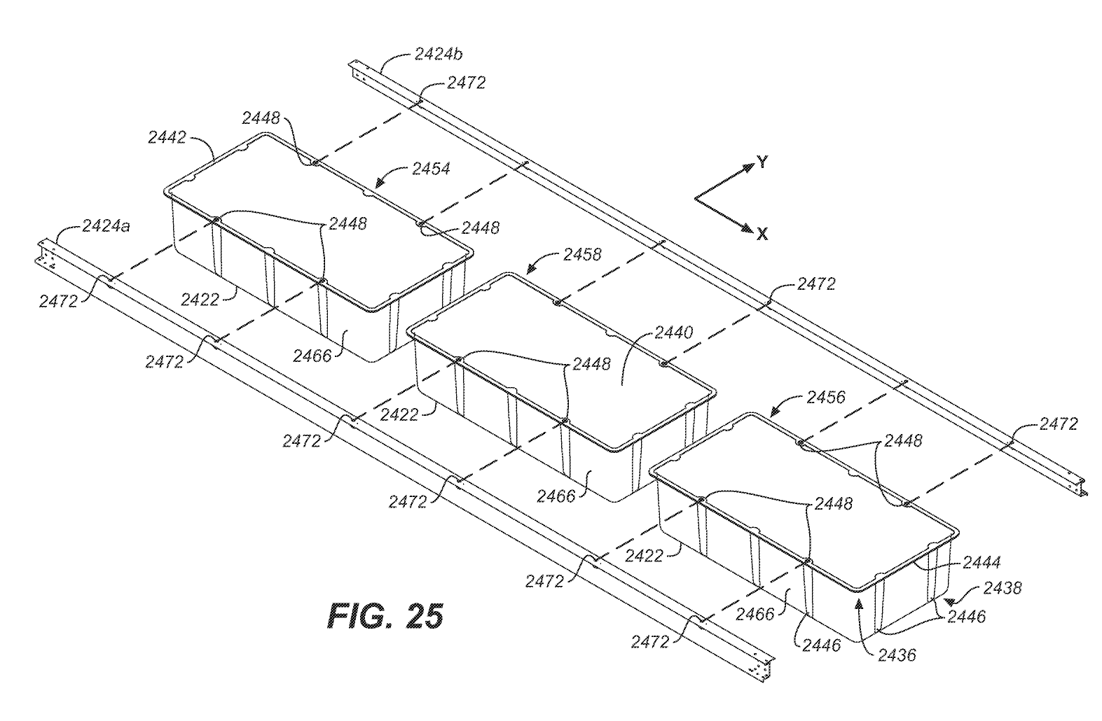

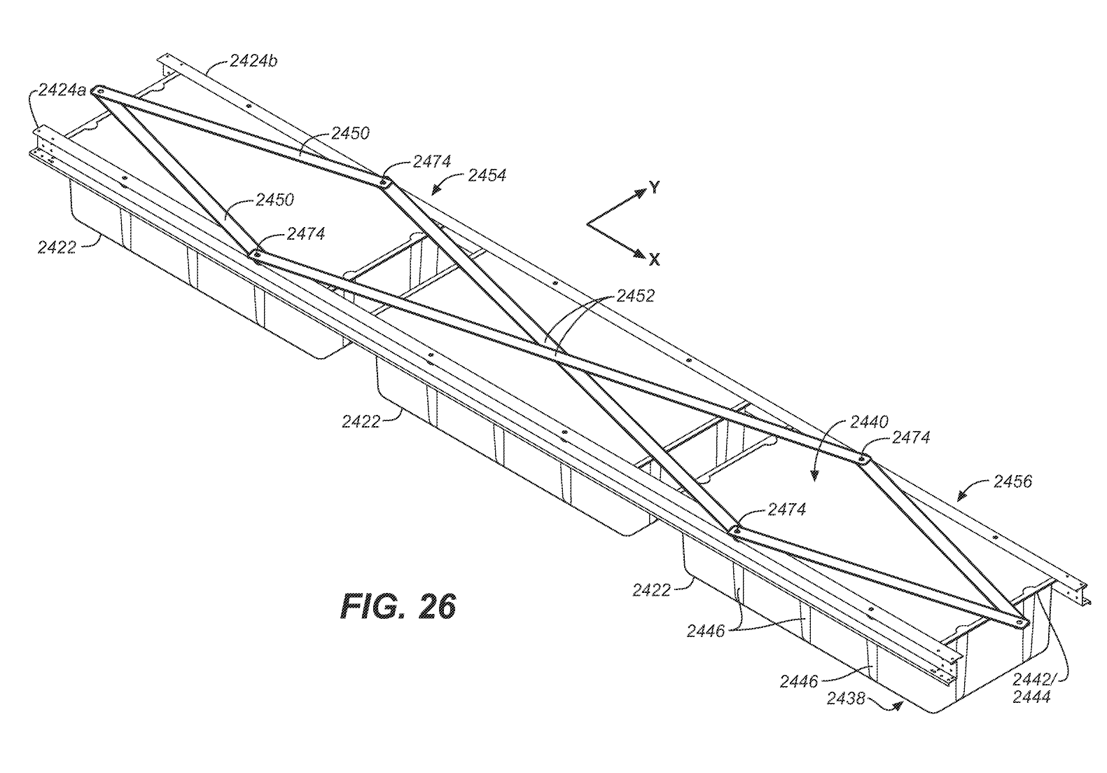

FIGS. 25 and 26 provide detail of the floats, E-W frame members. This view shows that in a preferred embodiment, the floats comprise generally cuboid boxes, either hollow or having a void filled with buoyant material, and having a bottom side 2438, a generally planar top side 2440, an upper edge 2442 surrounded by a perimeter ledge or flange 2444, and a plurality of bosses or solid mounting columns 2446 disposed along its sides, each having a threaded hole 2448 for threadable insertion of a structural bolt or screw downward into the mounting column in a generally vertical orientation. Three floats are shown, but the precise number selected for use is arbitrary and is a function of the size of the floats themselves in relation to the size of the array module desired.

Cross braces 2428, preferably in the form of flat metal straps, may be disposed on the top side of the floats and between the E-W frame members to create structural diaphragms that resist sheer and torsional forces applied to the assembly. In the configuration shown, a combination of short flat brace straps 2450 and long flat brace straps 2452 are employed to address the end floats 2454, 2456, and the middle float 2458, respectively.

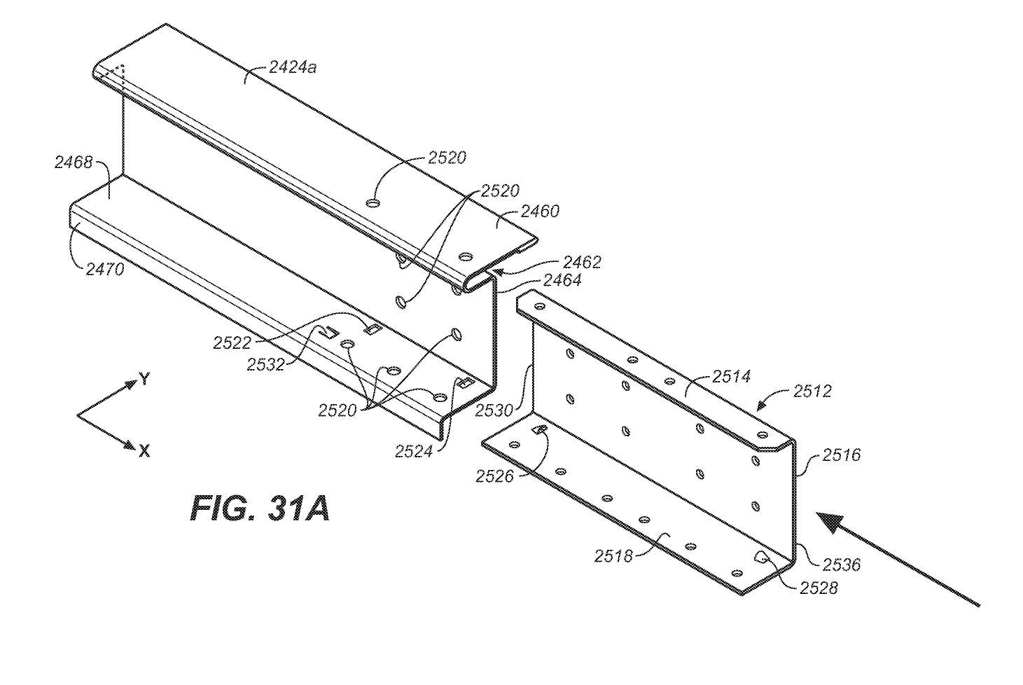

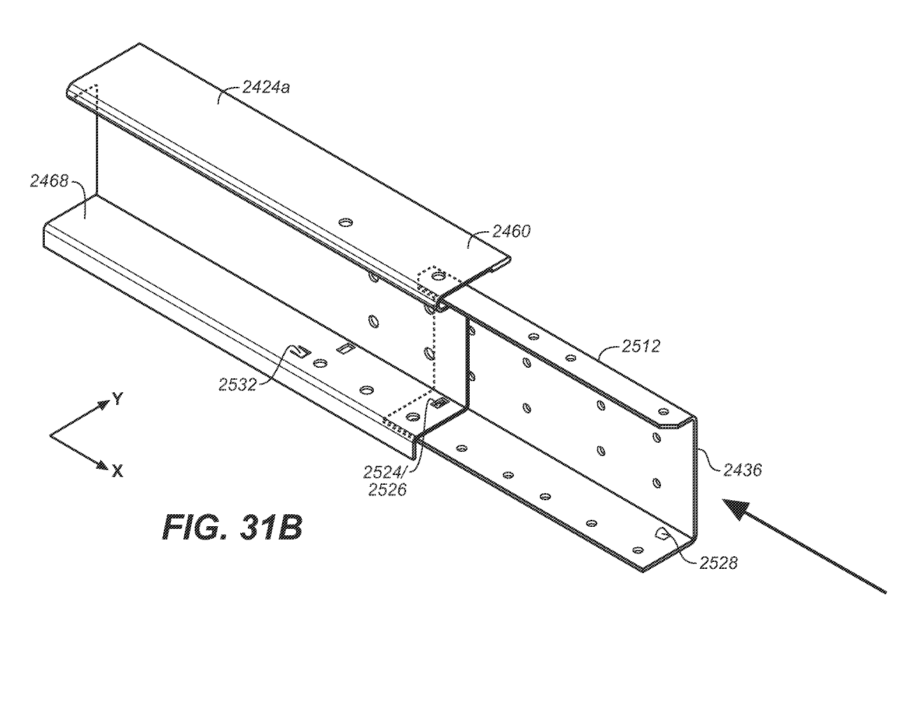

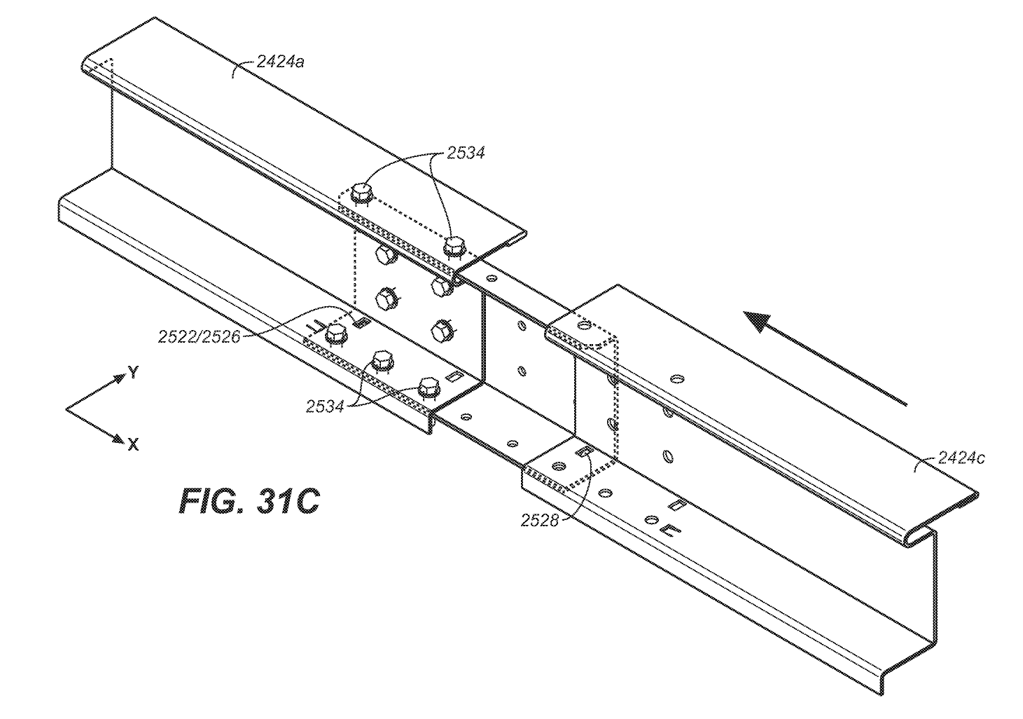

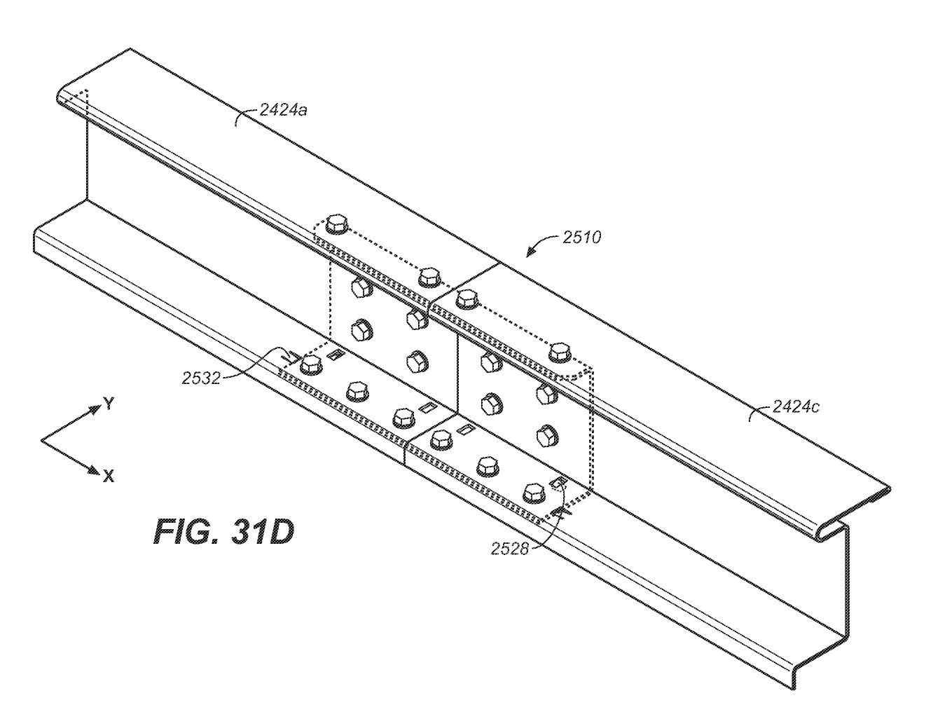

First and second E-W frame members 2424a, 2424b, straddle and effectively capture a plurality of floatation elements. The E-W frame members are preferably elongate rolled or extruded metal rails conformed to provide structural strength while being lightweight, optimally rigid, and corrosion resistant. The cross-sectional shape (best seen in FIGS. 31A-31D) includes an upper shelf 2460 which bends back upon itself to create a channel 2462 into which flange 2444 is inserted. The bend then turns directly downward to form a wall 2464 which engages the sides 2466 of the floats. The rail then bends again, this time outwardly, generally parallel to the upper shelf, to form a lower shelf 2468, which then terminates in a downward bend 2470.

The upper shelf of the E-W rails includes pre-drilled bolt holes 2472 that align with the threaded holes 2448 in the perimeter flange 2444 on the floats. Accordingly, by sliding the flange into the channel 2462 in the E-W rail and aligning the pre-drilled bolt holes in the rails with the holes in the mounting columns 2446, the floats can be precisely positioned and spaced between the rails. Cross brace straps having bolt holes 2474 proximate their ends can be installed on the rails and floats concurrent with the placement of screws in appropriate rail holes 2472.

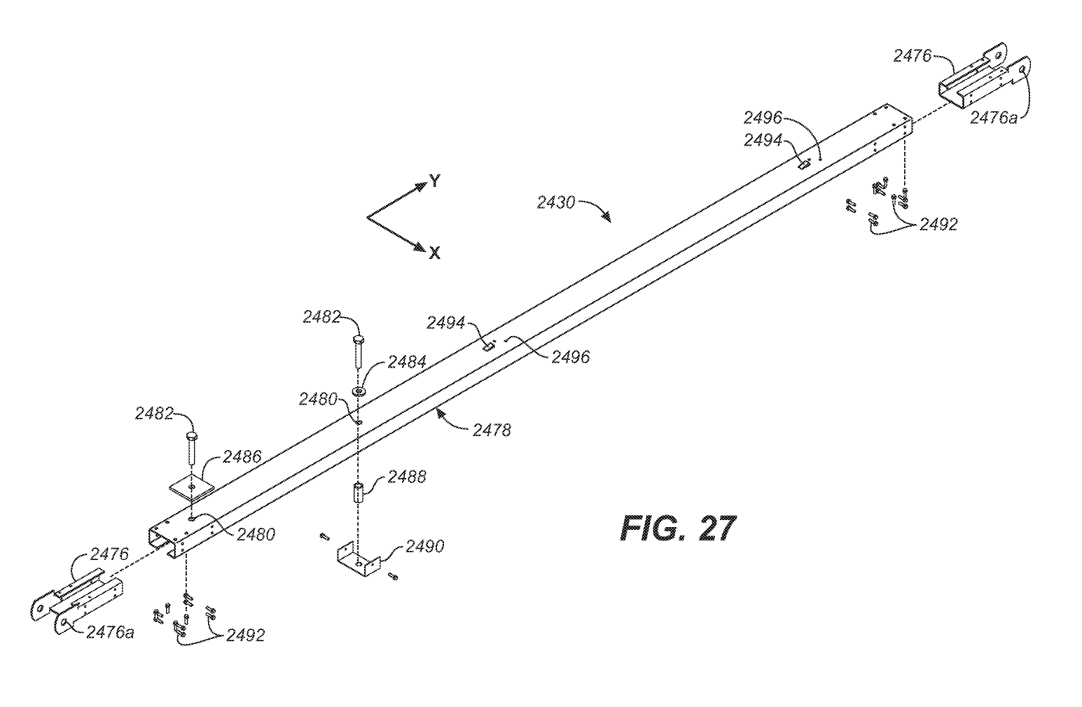

FIG. 27 shows detail of the N-S frame members 2430 as well as the hinge connectors 2476 used for coupling N-S frame members with N-S frame members on adjoining array modules. Each N-S frame member preferably comprises an elongate hot rolled C channel or box channel laid gap side 2478 down and having bolt holes 2480 that can be aligned with bolt holes 2448, 2472, 2474 in the E-W frame members, cross brace straps, and mounting columns, respectively. A bolt 2482 is placed through each hole to secure the entire combination to the float and washers (ring 2484 and/or plate 2486) can be employed to distribute pressure on the channel's upper surface. The connected over the inboard (northernmost) E-W frame member may include a cylindrical spacer 2488 to prevent buckling of the C channel upon tightening the connecting bolt and a U-shaped bracket or track stiffener 2490 to grip the C channel, prevent even slight lateral migration of the C channel, and thereby increase rigidity, strength, and stability.

Each end of the N-S frame member may be provided with a hinge connector 2476, which is secured in the end through a plurality of small bolts or self-tapping screws 2492.

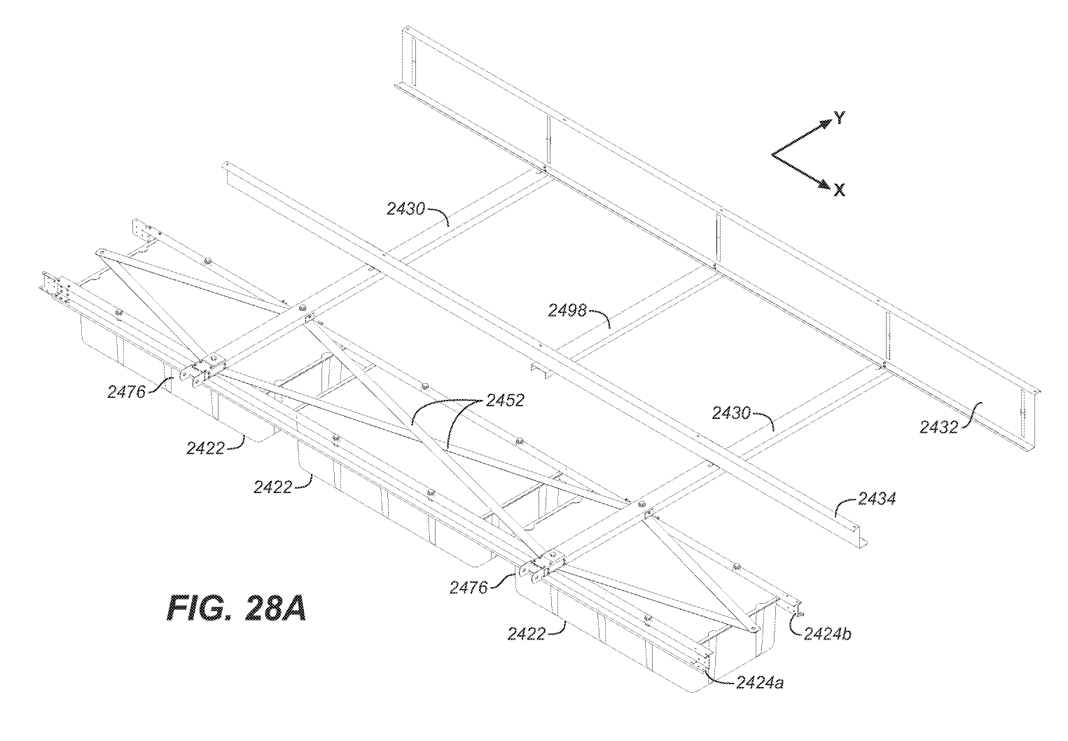

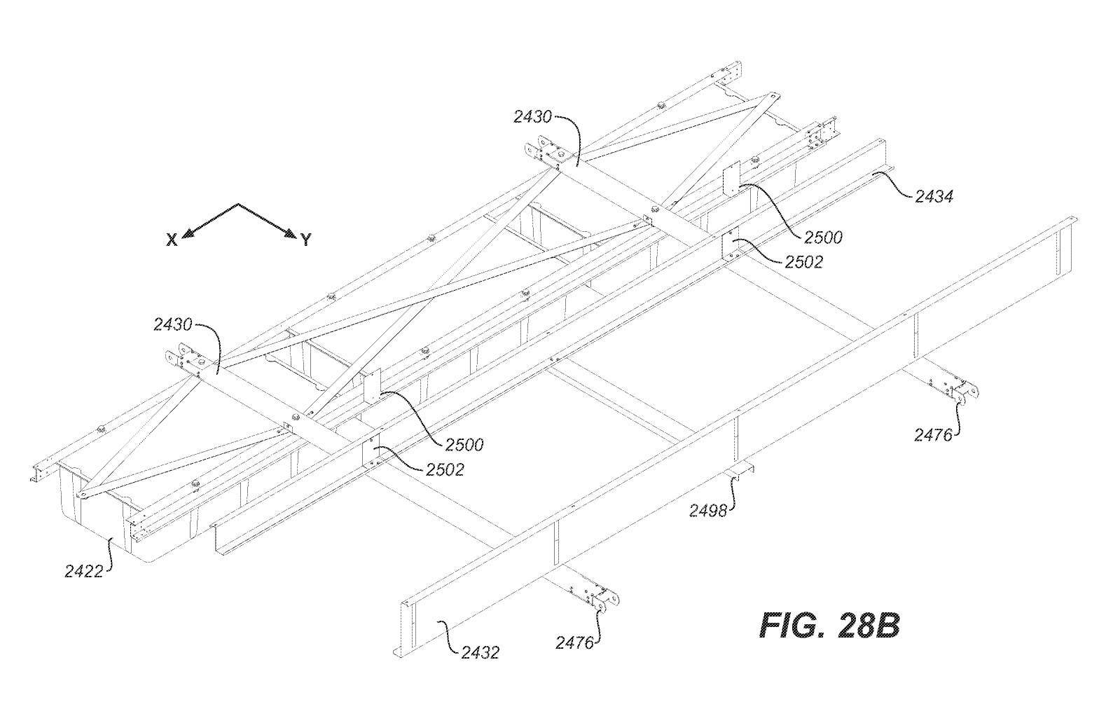

Disposed between the ends of the frame member, two dimples or stops 2494 provide an element against which the lower end of north and south panel supports can be abutted. Holes 2496 provide means for positioning, indexing, and connecting the N and S panel supports, 2432, 2434, respectively, to the frame members using screws. FIGS. 28A-28b show the installation of the N-S frame members atop the E-W frame members, which are in turn mounted to the floats. The panel supports are mounted transversely across the N-S frame members and are preferably Z shaped rolled sheet metal with stiffeners, as needed, to support the weight of a plurality of panels mounted on their upper edges. A medial bridging element 2498, preferably a short length of C channel, extends between and connects the bottom sides of the panel supports. Angled brackets 2500 (els) can be provided to increase structural rigidity at the panel support connections 2502.

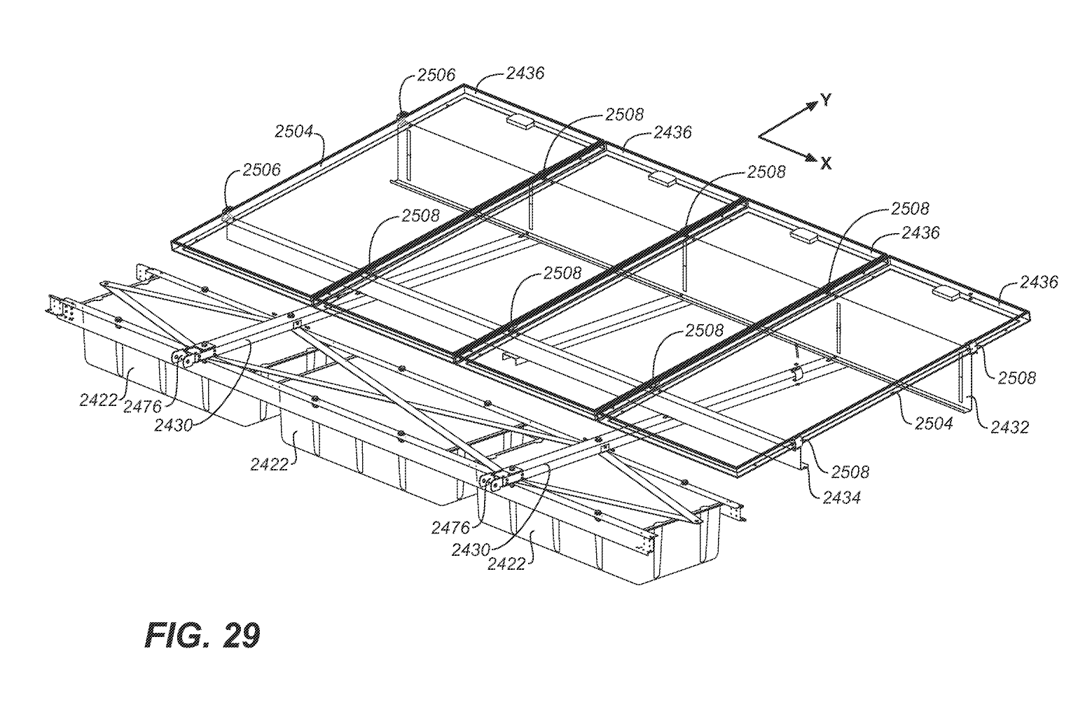

FIG. 29 shows how solar panels 2536 are mounted on and connected to the panel supports by clipping the outer edges 2504 of the outer panels to the panel supports using C-clips 2506 and screws, and by clipping the interior edges of all of the panels to the panel supports using panel T-clips 2508 and screws.

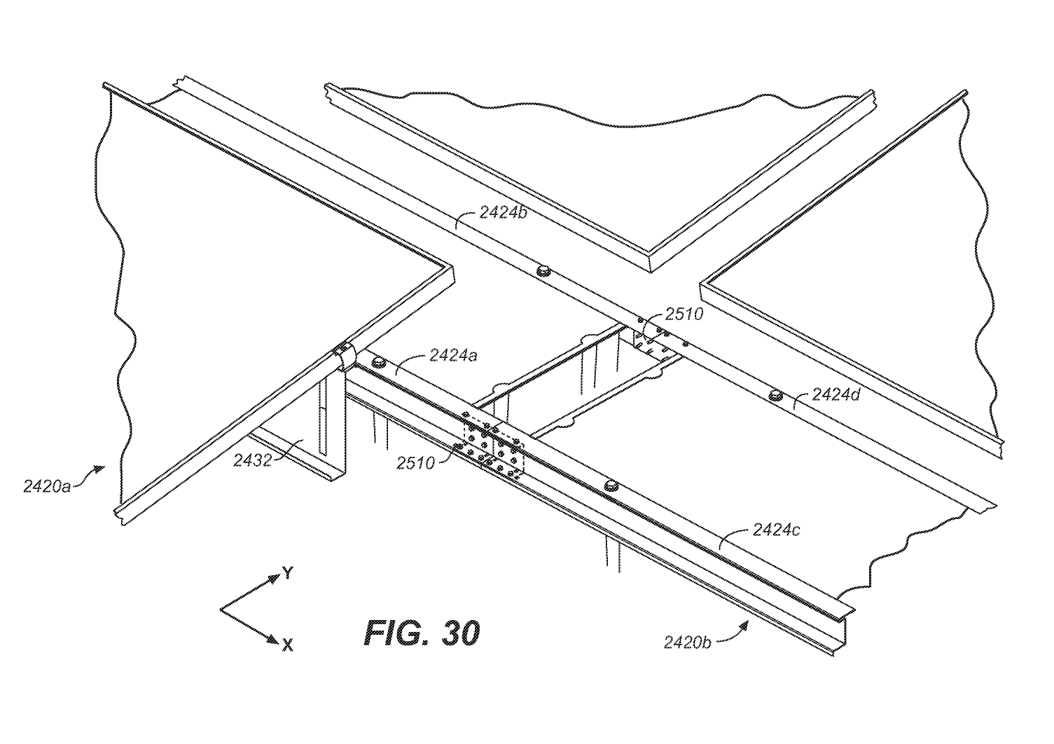

Referring next to FIG. 30, there are shown connections 2510 made between east-west frame members 2424a to 2424c, and 2424b to 2424d, of adjoining array modules 2420a, 24120b. FIGS. 31A through 31D show how the connection is accomplished. The principal structural element through which the connection is achieved is a novel splice 2512, which is configured to insert as a male element into the channel 2462 also used for inserting float flange 2444. The splice is shaped with an upper ledge 2514, a side wall 2516, and lower ledge 2518 that are contoured to conform closely to the sides of the E-W frame member under upper shelf 2460, along wall 2464, and under lower shelf 2468. The end of the E-W frame members include holes 2520 for screws as well slots 2522, 2524, the slots being adapted to permit insertion of a dimple 2526, (2528 for the corresponding E-frame member). As splice is inserted into and alongside E-W frame member 2424a, dimple 2526 first engages and inserts into slot 2524, and the splice is thereby retained and prevented from being pulled out from the frame member [see FIG. 31B]. The splice can then be further inserted into and along the frame member until dimple 2528 engages and inserts into slot 2524, at which point the first end 2530 abuts stop 2532 depending downwardly from lower shelf 2468. Accordingly, splice 2512 is effectively held in place. Self-tapping screws 2534 are then installed through aligned holes in the splice and frame member. Once fully installed in a first E-W frame member 2424a, a second E-W frame member 2424c can be brought into proper alignment for insertion of the second end 2536 into and alongside the second E-W frame member. The process is duplicated until full insertion is achieved [see FIG. 31D], at which time the ends of the E-W frame members are abutted.

In application, the mechanical advantages of the splice are considerable. Assembly of large floating units in a marine environment is virtually an athletic achievement. The circumstances of the installation call for manual coupling of the floating units working in small teams. Accordingly, as small surface motions move the units in ever possible direction, installers must bring the ends of the E-W frame members into alignment and proximity sufficient to effect the splice insertion. Once that is accomplished, the water movement continues to push, pull, lift, drop and otherwise move the frame member ends in every direction. Because the final connection and coupling of the units requires aligning screw holes of the frame members and the splice, it is critical that the splice does not allow migration out from the frame members as coupling progresses. Accordingly, as the dimples engage a first slot, the frame members are brought into substantial alignment, and they are held in place and prevented from separating as they are more fully approximated using the splice as a kind of indexing element, until the dimple engages the second slot, where it is fully retained.

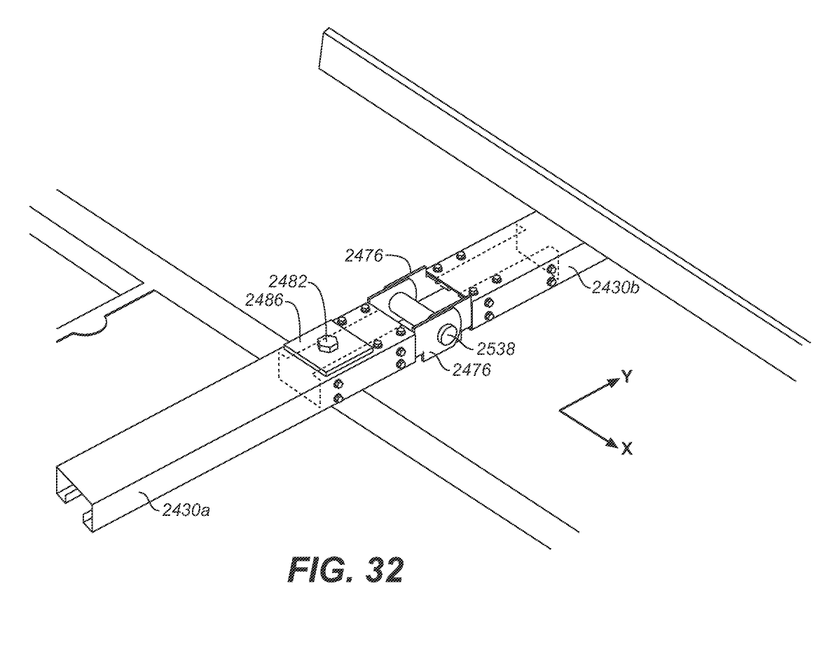

FIG. 32 shows the hinged connection between N-S frame members 2430a, 2430b in adjoining array modules. The hinge connectors include pin holes 2476a, such that when the hinge connectors 2476 are approximated and their holes aligned, a hinge pin 2538 can be inserted and secured with a washer and cotter pin (not shown) to provide an axis about which N-S frame members can pivot.

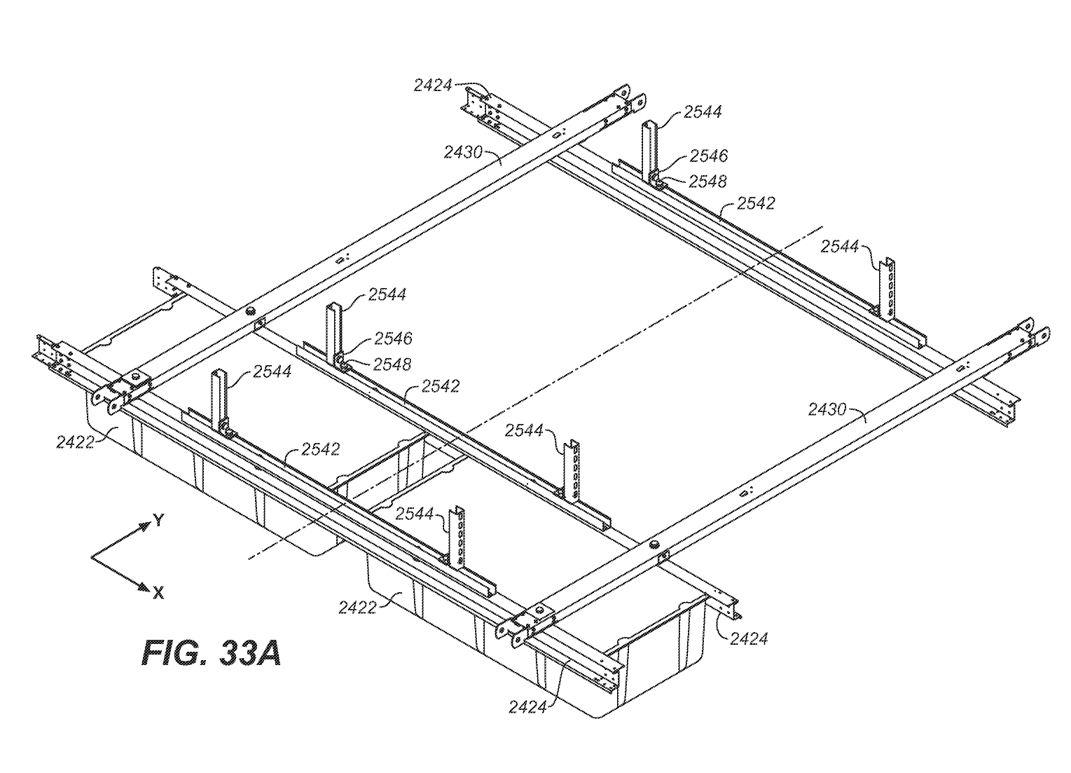

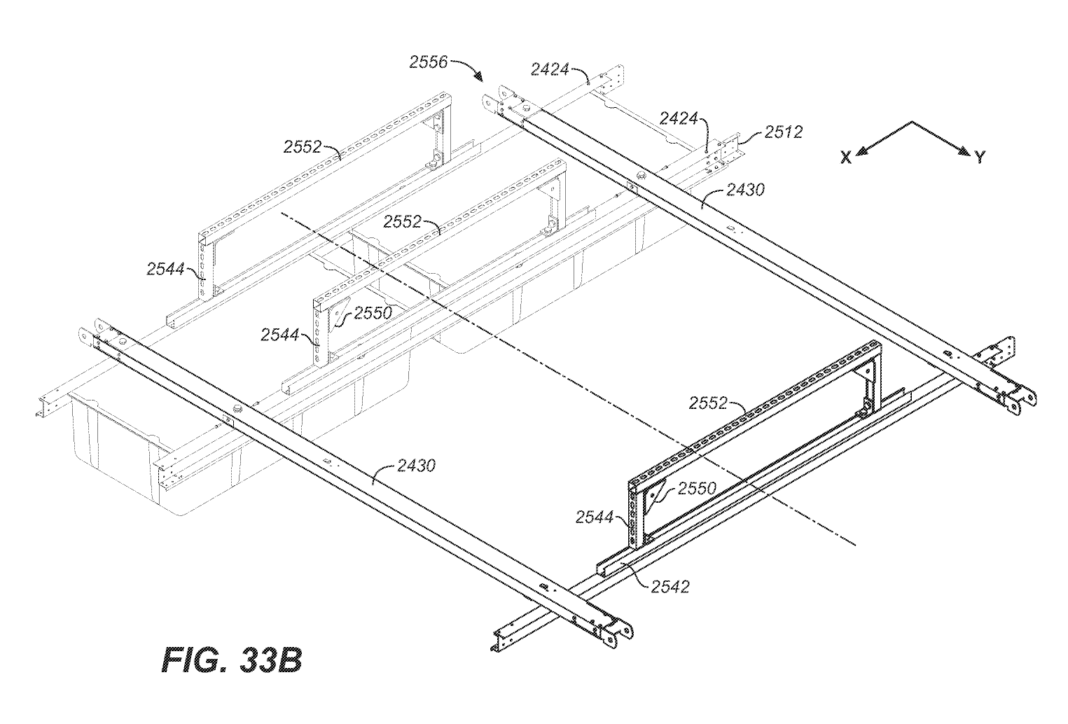

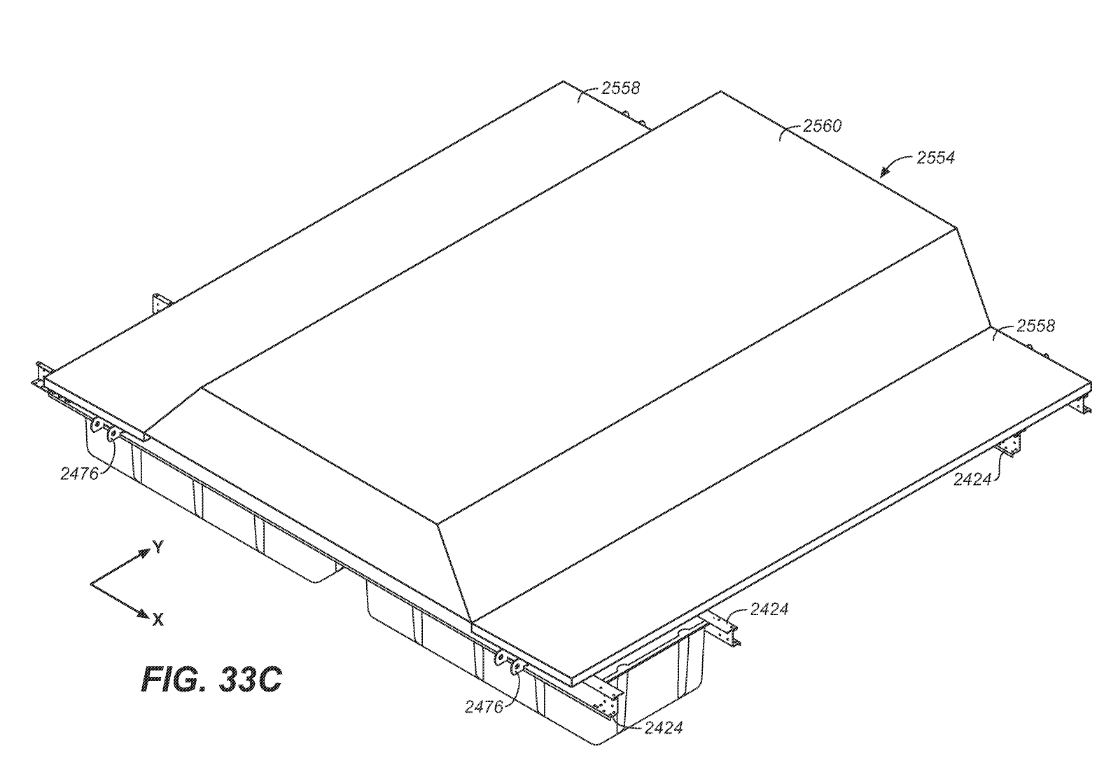

FIG. 33A through 33C shown the assembly of support elements for a N-S wireway/walkway. As with the array modules, the wireway/walkway support structure uses floats 2422, E-W frame members 2424, and N-S frame members 2430. The E-W frame members may be shortened to span the length of only two, rather than three floats. Three elongate C channels 2542 are mounted atop the E-W frame members and provide structure upon which vertically disposed posts 2544 may be attached using angles 2546 and bolts 2548. Shelf brackets 2550 can be installed at the uppermost portion of the posts to support horizontal beams 2552. When the support elements are in place, a cover 2554 may be placed over the entire wireway/walkway unit 2556, the cover including walkway portions 2558 and a wireway cover portion 2560.

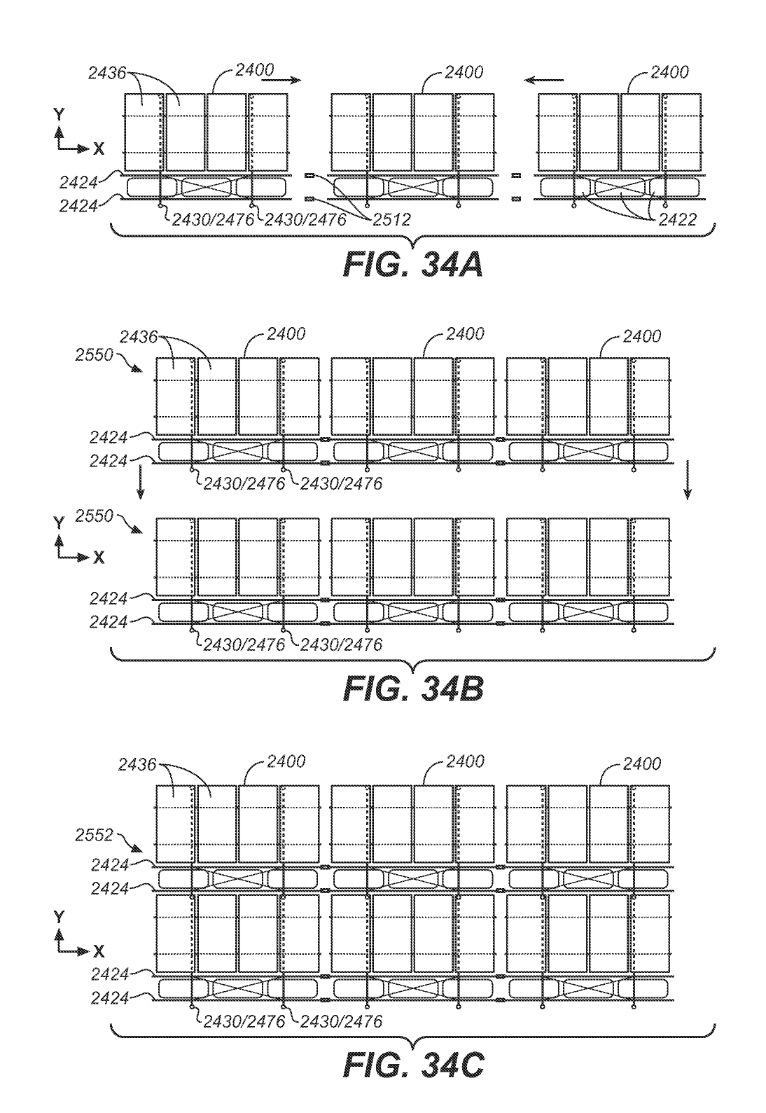

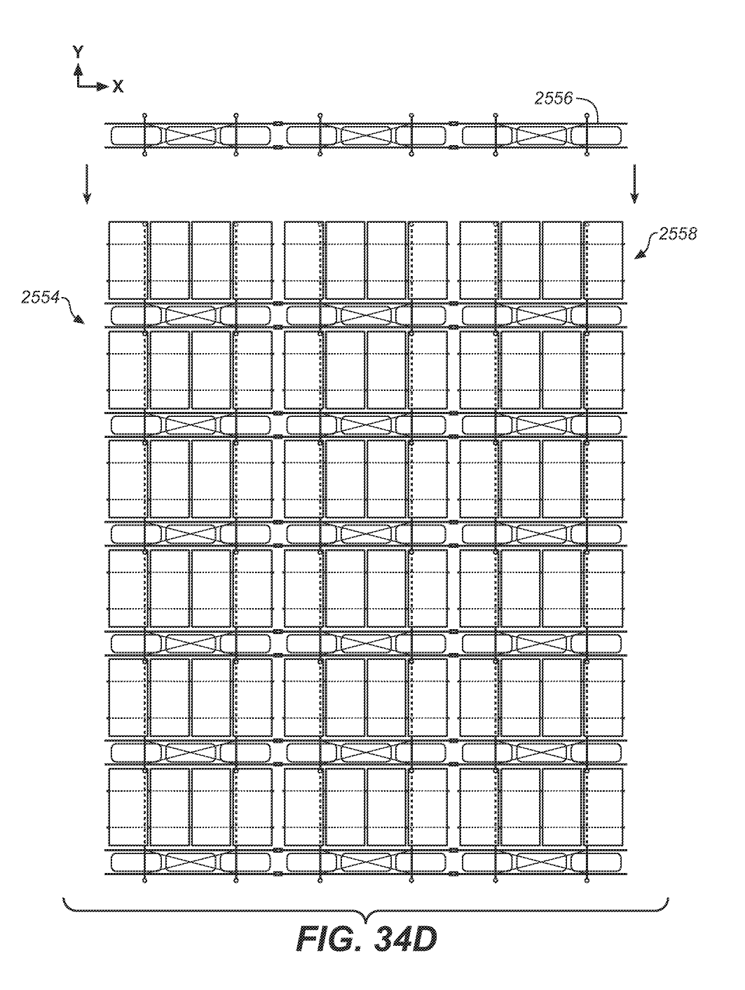

FIGS. 34A-34D are schematic top plan views showing an assembly scheme for the array modules, first involving the coupling of single array modules 2400 in the east-west direction by connecting E-W frame members 2424 using splices 2512 to create a three-module row 2550 [FIG. 34A], then connecting the three-module row into larger units 2552 comprising array modules in multiples of three in the north-south direction using the hinge connectors 2476 on the N-S frame members 2430 [FIGS. 34B-34C]. A complete array field or a portion of a field 2554 is completed by coupling a connected E-W line of floatation elements 2556 to the northernmost set of array modules 2558 of the field.

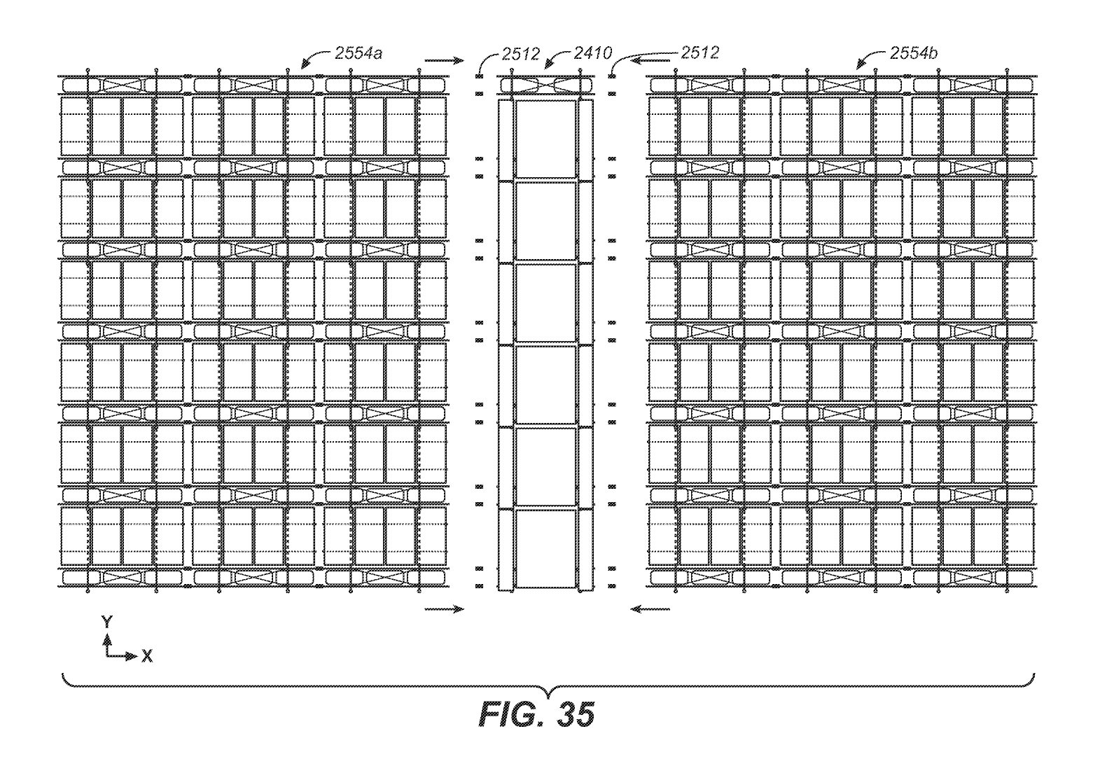

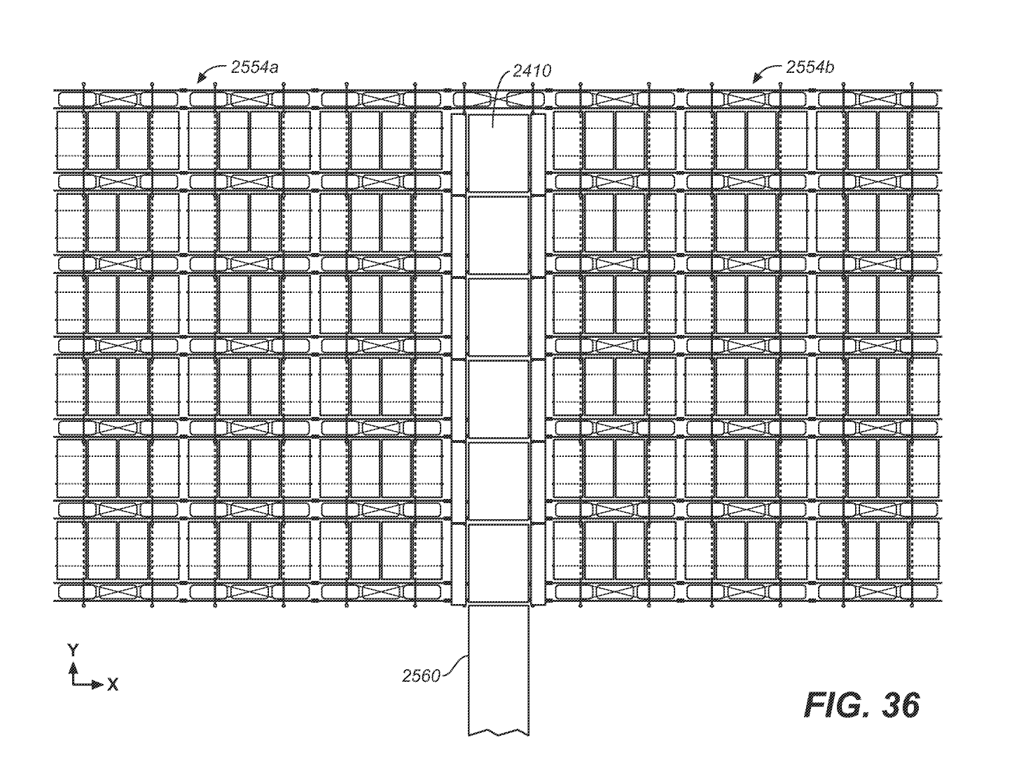

FIGS. 35 and 36 show how two iterations 2554a, 2554b, of the field assembled above can be joined on the water by coupling each to a medial walkway in the E-W direction simply by aligning the fields and using splice 2512 at each E-W frame member junction.

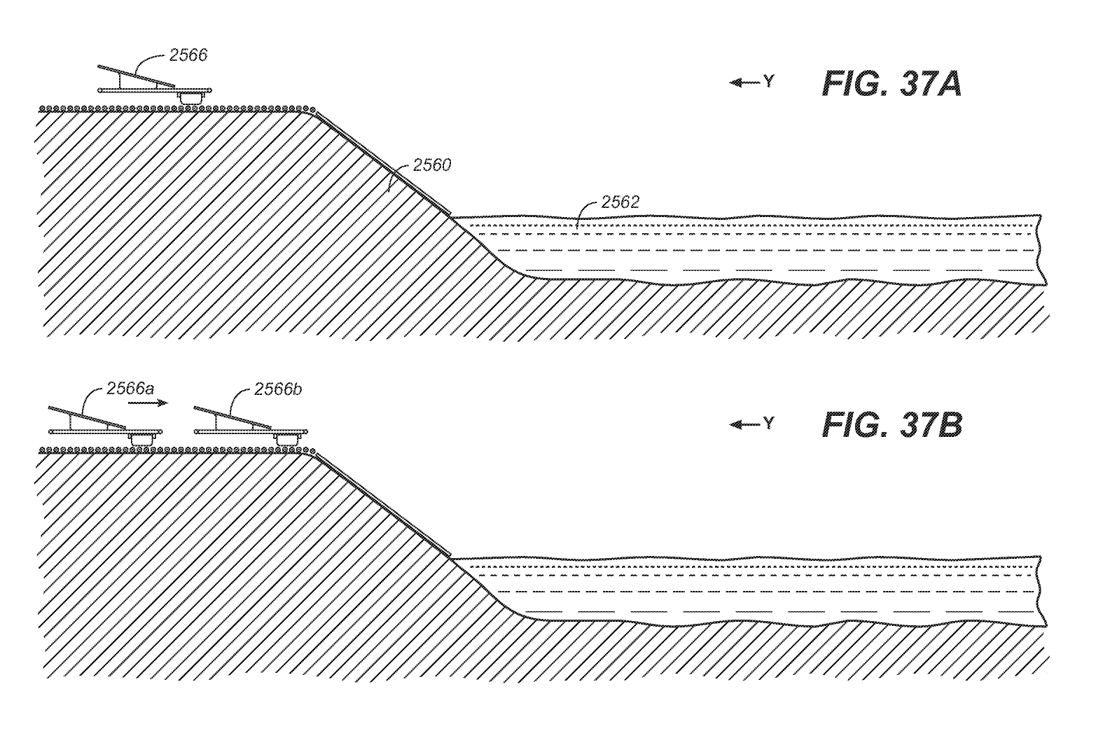

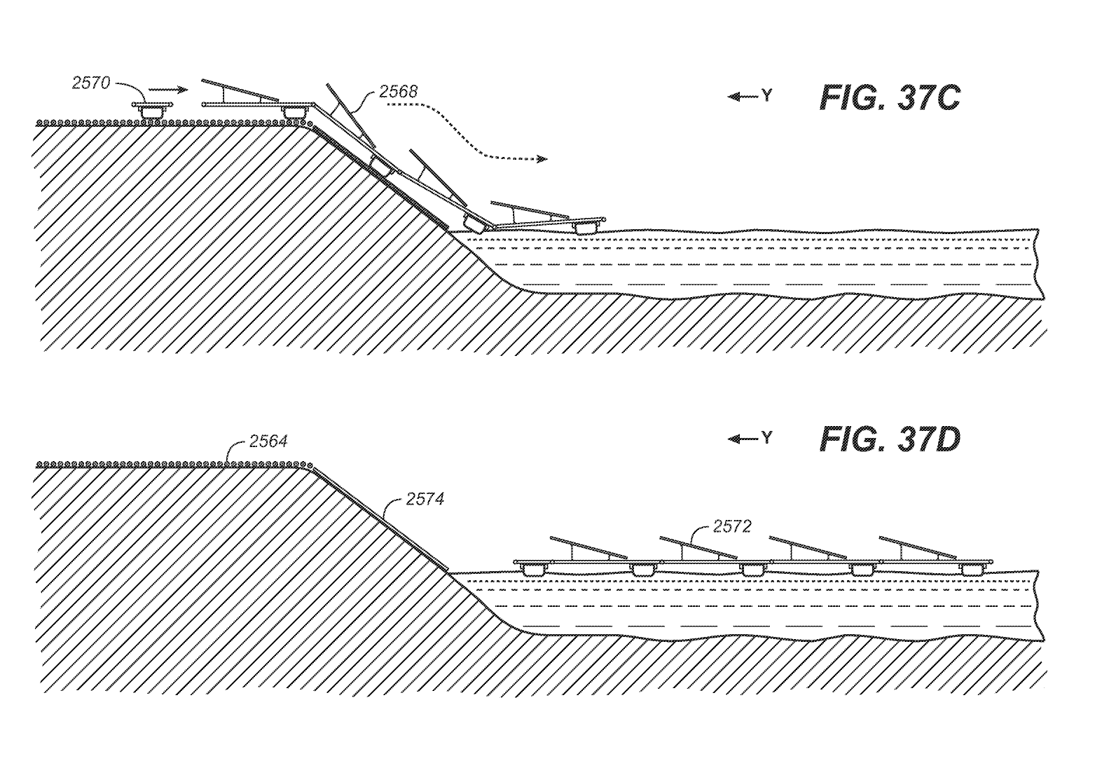

FIGS. 37A-37D are highly schematic side views in elevation showing that the assembly scheme described in connection with FIGS. 34A-D, above, can be accomplished on the bank, berm or other ground 2560 surrounding a body of water 2562. Accordingly, individual array modules can themselves be assembled on a conveyor system 2564, in this instance shown schematically as a roller conveyor (e.g., skate- or cylindrical rollers). The array modules can then be coupled to make rows 2566 of three, four, or more array modules, as described above, and then further into units comprising multiples of rows 2566a, 2566b [FIG. 37B], and so forth, until a predetermined number of rows are connected 2568. Depending on whether further rows are ultimately to be added to this block of array modules, it can be completed into a discrete floating array by coupling a terminal E-W line of floats 2570 to the assembled rows. Once a block of array modules is ready for deployment on water, the entire block 2572 can be moved over the roller conveyor and allowed to slide into the water over a suitable ramp 2574.

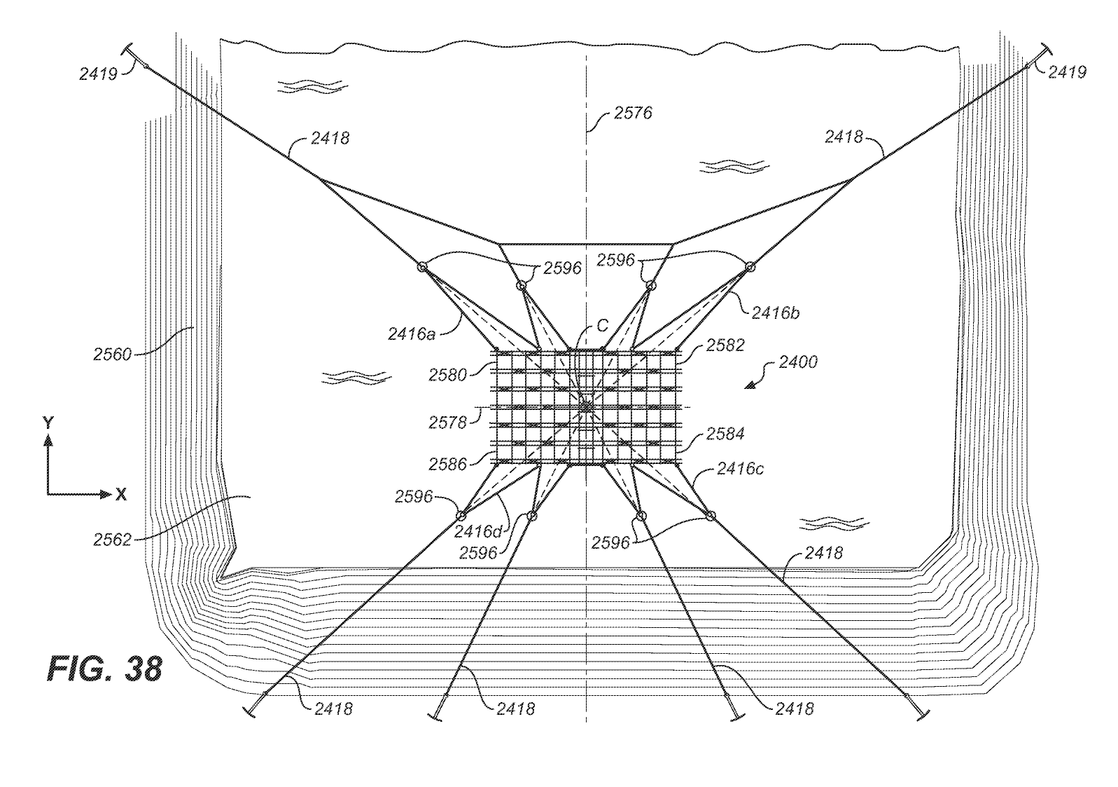

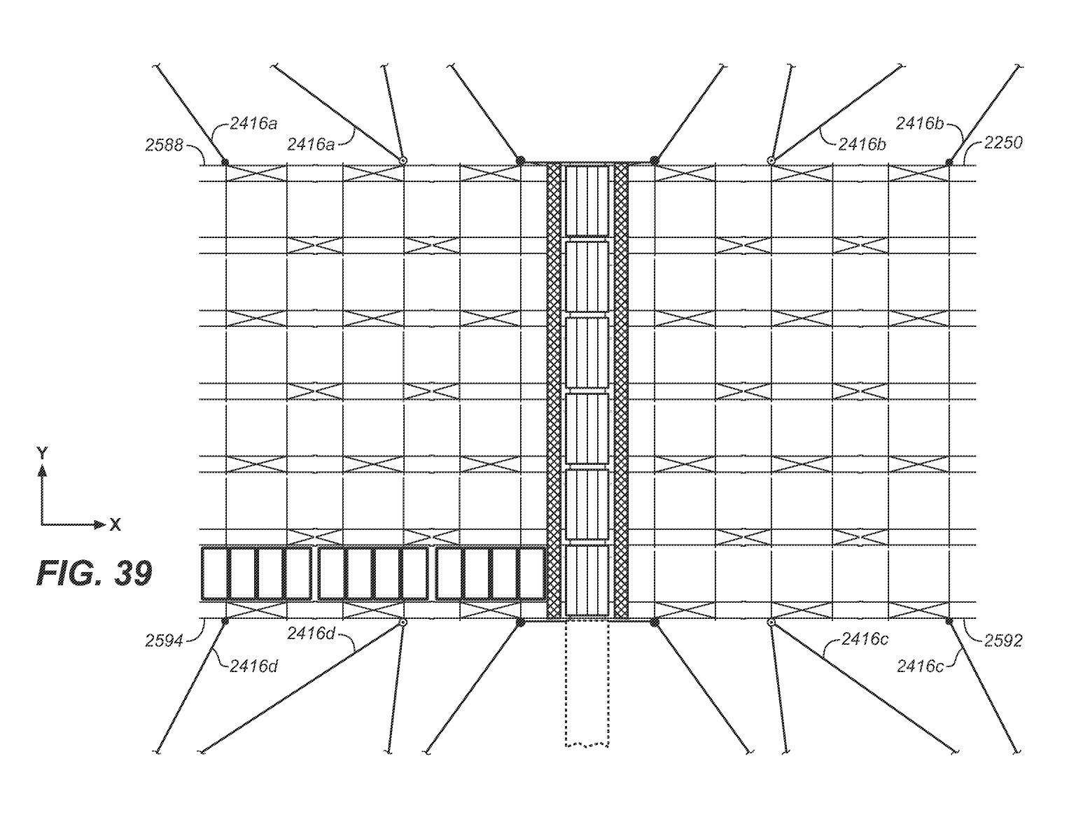

Referring next to FIGS. 38 and 39, there is shown in schematic top plan views the mooring approach used to stabilize and protect an array field of the present invention. From these views it will be seen that a field will naturally and typically assume a generally rectangular or square geometry, though such a geometry is by no means necessary. Indeed, the array field can assume a very irregular shape as it may be conformed to the area shape of the body of water on which it is installed. Assuming, however, that in most instances the installation will occupy substantially less the entire available water surface area, regular geometries will simply the installation, and with such geometries, the array field can be divided into quadrants for easy reference, using the medial N-S axis 2576 and the medial E-W axis 2578 as dividing lines. Under such a mapping, the array field includes NW, NE, SE, and SW quadrants, 2580, 2582, 2584, and 2586, respectively. The mooring and anchoring system of the present invention uses a single continuous running line for each of the four quadrants, thus 2416a, 2416b, 2416c, and 2416d. Each continuous running line at one end at a connection located at a corner of the array, 2588, 2590, 2592, 2594. (The structural and operational features of the connections are described in detail below.) The line then extends outwardly from the array until it reaches a mooring buoy 2596, which includes a pulley attached to a shackle coupled to a ring integrated into the top of the buoy. The line is routed back to the array, where it is either fed through a pulley mounted at the end of a N-S frame member or terminated at a cleat. One buoy is provided for every two continuous line connection points on the array, whether those connection points are fixed connections or pulleys.

Also secured to the buoys are static cables 2418, which extend back to shore 2560 where they are secured to a deadman anchor 2419. When the array field is in a neutral position, such as shown in FIG. 38, each static line on one side of the array field has a counterpart which is a geometric extension of the line passing from a first static cable, through the geometric center C of the array field, and then extending into a static line on the opposite side of the array field. Since in a square or rectangular array the opposing borders of the array are substantially parallel, the opposing static cables and their geometric extensions are essentially transversals oriented about the center of the array.

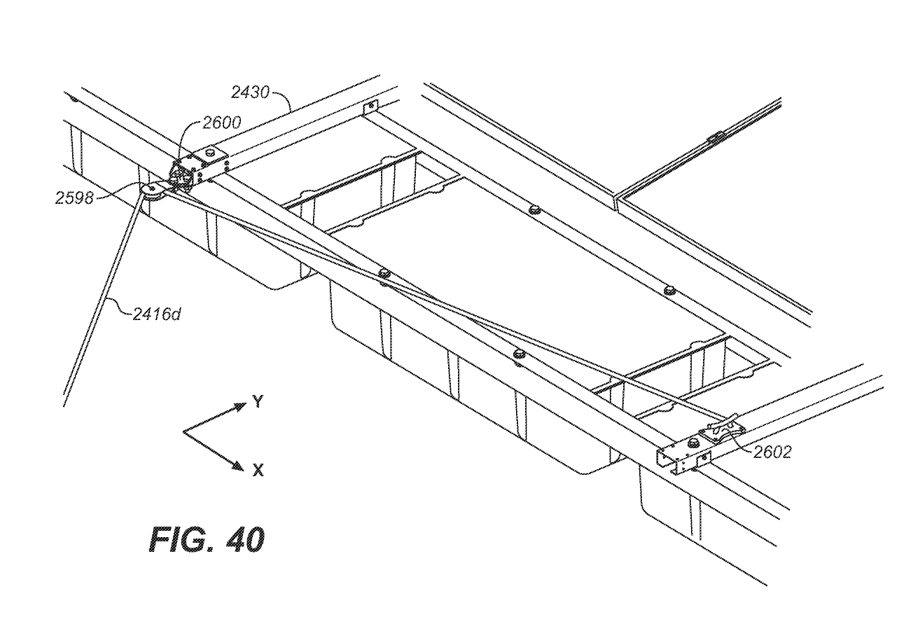

FIG. 40 shows a south interior mooring connection, wherein the continuous line 2416d is routed from a mooring buoy (not shown) through a pulley 2598 mounted on a mounting plate 2600 affixed to the end of a N-S frame member in the southwest quadrant of an array field. The continuous line then extends to a cleat 2602 where it is terminated in an appropriate mooring knot, such as a cleat hitch.

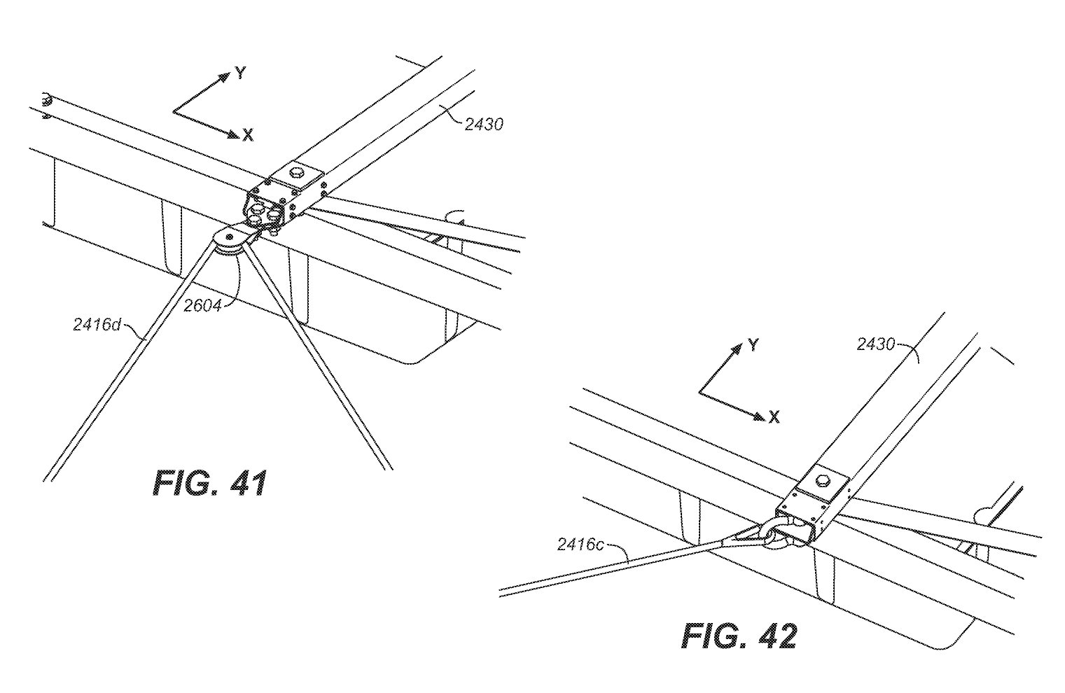

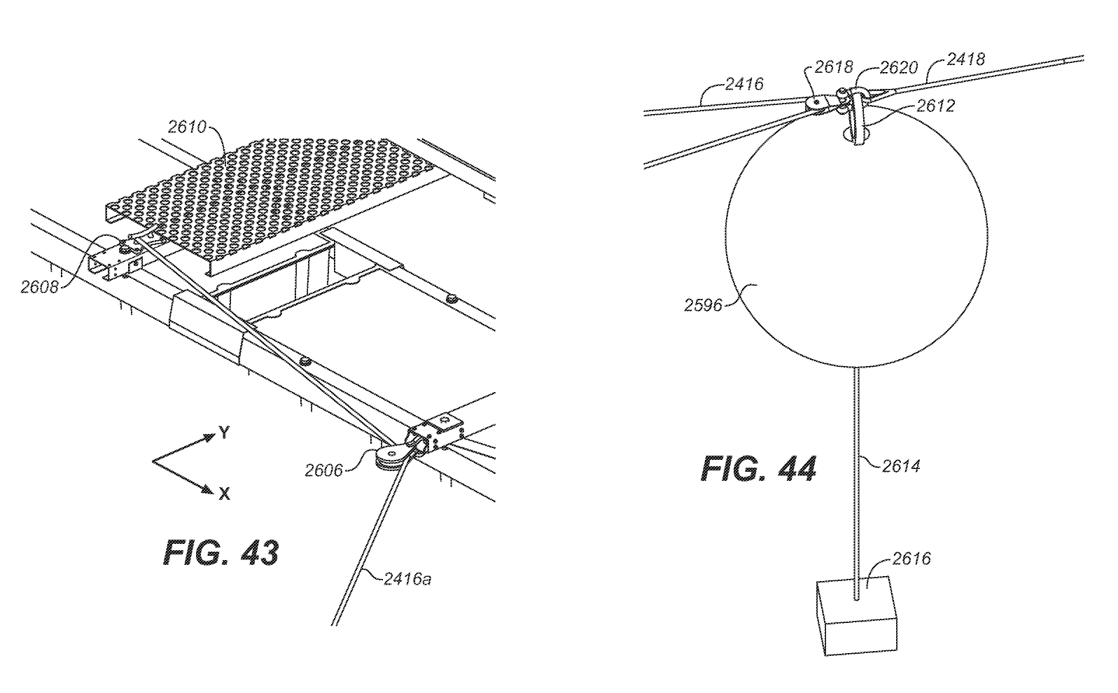

FIG. 41 is an array mounted medial pulley 2604 for the mooring system. FIG. 42 shows a corner attachment for a continuous line 2416c using a shackle 2606 mounted on the end of a N-S frame member 2430. FIG. 43 shows a continuous mooring line in the NW quadrant of the array field threaded through a pulley 2606 and terminated at a cleat 2608 on the end of a N-S frame member 2430 under the walkway portion 2610 of a N-S wireway/walkway.

FIG. 44 shows a spherical mooring buoy 2596 employed to keep mooring lines out of the water so as to prevent damage, corrosion, and fouling of an intermediate pulley. The buoy includes an apical ring 2612 which is held in an upright position by cable 2614 or chain weight disposed from the bottom of the buoy and extending down to a ballast weight 2616. A static cable 2418 is connected to the apical ring at one of its end and extends back to land where it terminates at its other end in a deadman anchor 2419 [shown in FIG. 38]. A pulley 2618 is also attached to the apical ring using a shackle 2620.

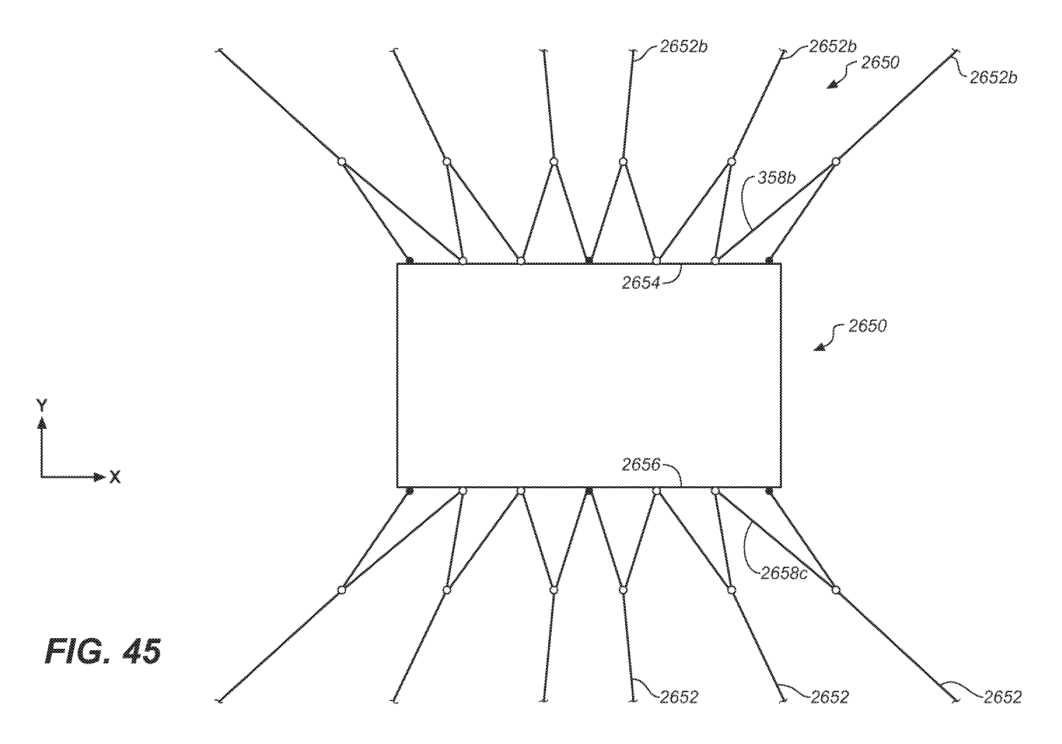

FIG. 45 is a highly schematic top plan view of the mooring approach of the present invention installed on a rectangular floating array 2650. In this view, with no forces acting differentially on any part of the array field, the loads are equally resisted by all anchors.

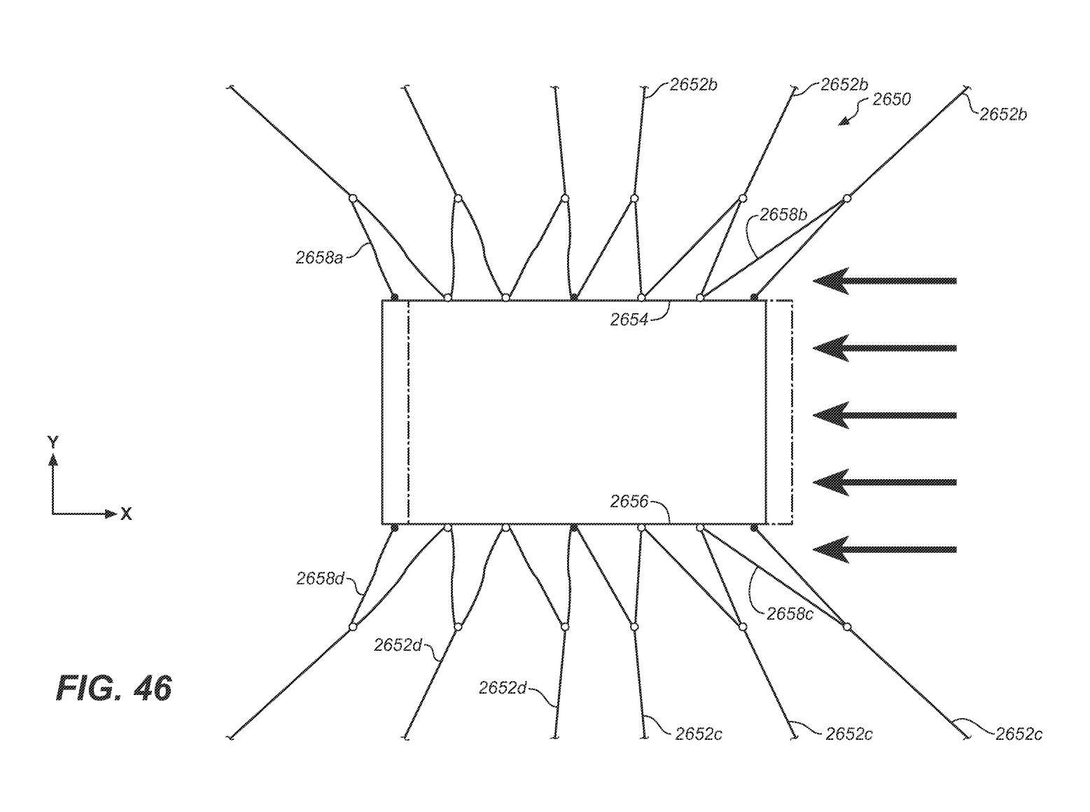

FIG. 46 shows the response of the mooring system to a lateral translation of the floating array in a westerly direction due, for instance, to an east wind. With this displacement, the force is resisted generally equally by the NE and SE quadrant anchors 2652b, 2652c with the load distributed along the entire quadrant boundaries, 2654, 2656 by the continuous lines 2658b, 2658c connected to the NE and SE quadrant static cables 2660b, 2660c. The NW and SW quadrant continuous lines 2658a, 2658d, become slack lines, with the anchors 2652a, 2652d for those quadrants not involved in resisting wind force.

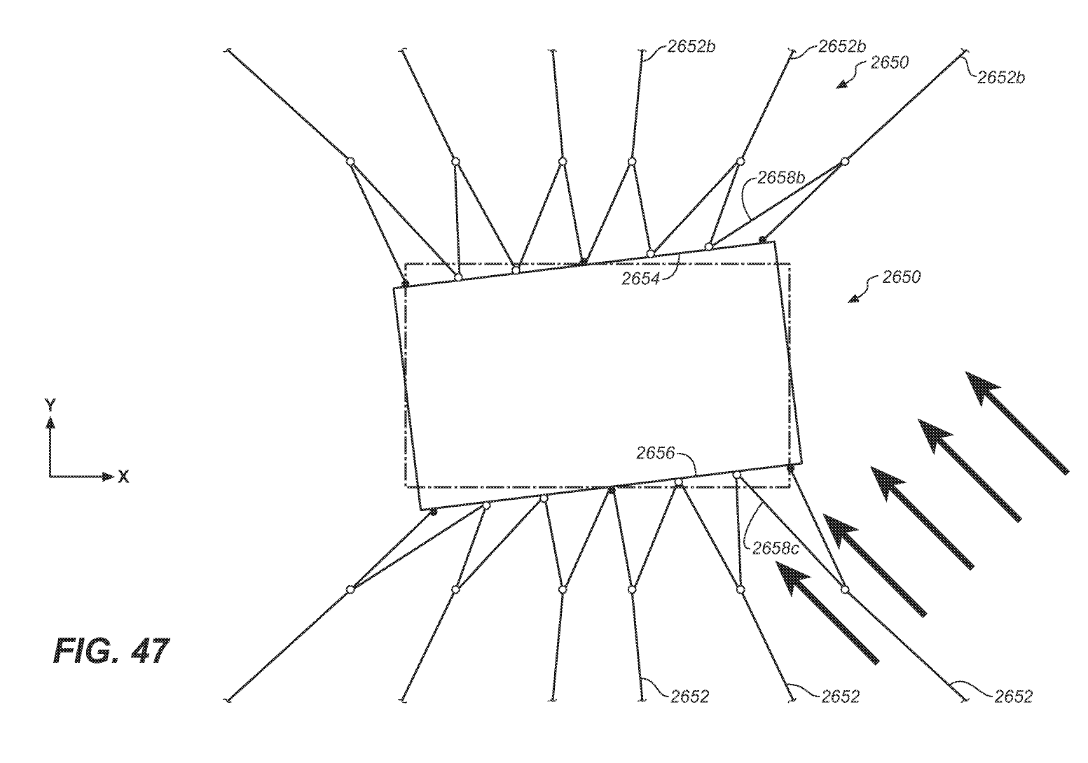

FIG. 47 shows the response of the same mooring system as the array is rotationally displaced by a southeasterly wind. In this situation, all anchors resist rotation and continuous running lines for each quadrant distribute loads evenly across the quadrant boundary.

The above disclosure is sufficient to enable one of ordinary skill in the art to practice the invention, and provides the best mode of practicing the invention presently contemplated by the inventor. While there is provided herein a full and complete disclosure of the preferred embodiments of this invention, it is not desired to limit the invention to the exact construction, dimensional relationships, and operation shown and described. Various modifications, alternative constructions, changes and equivalents will readily occur to those skilled in the art and may be employed, as suitable, without departing from the true spirit and scope of the invention. Such changes might involve alternative materials, components, structural arrangements, sizes, shapes, forms, functions, operational features or the like.

Therefore, the above description and illustrations should not be construed as limiting the scope of the invention, which is defined by the appended claims.

1. (canceled)

2. A floating support structure for a solar panel array, comprising:
a plurality of floatation elements;
a framework comprising East-West frame members connected to and aligning said floatation elements, and North-South frame members providing a base on which panel supports are installed, said framework and floatation elements combining to form array modules;
coupling hardware for connecting said framework of said array modules to adjoining modules in both the E-W direction and N-S direction;
a plurality of solar panels for mounting on said array modules;
one or more wireways/walkways disposed between and connecting said array modules in large array fields; and
a mooring and anchoring system securing the solar panel array to shore and distributing loads along large portions of the array.

3. The floating support structure of claim 2, wherein said framework includes a combination of diagonal trusses for coupling said East-West frame members and at each of said floatation elements so as to form East-West beams, and Vierendeel trusses connecting said East-West beams and said North-South frame members, said combination providing global array field stability by transferring the wind forces from the array field to predetermined mooring support points.

4. The floating support structure of claim 3, wherein when said the frame members are connected, secondary walkways are defined in an area between connected adjoining array modules and generally oriented in an East-West direction.

5. The floating support structure of claim 3, wherein each of said wireways/walkways run in a generally North-South, and include an elevated housing for electrical equipment, such as electrical wires, combiner boxes, and disconnects.

6. The floating support structure of claim 5, wherein said electrical equipment is disposed generally along the surface of said wireways/walkways in said housing.

7. The floating support structure of claim 5, wherein said wires emerge from said housing proximate an end of said housing and are thereafter submerged before being directed to shore.

8. The floating support structure of claim 7, wherein said wireways/walkways include wire dividers to separate electrical wires for promoting heat dissipation.

9. The floating support structure of claim 2, wherein said mooring and anchoring system includes a plurality of continuous lines threaded through running pulleys attached so said array, thereby providing a constant tension force in said continuous mooring lines, wherein lateral wind load forces imposed on the array are generally constant in magnitude and vary in direction based on the geometry of said mooring lines.

10. The floating support structure of claim 9, wherein a solar panel array is divided into quadrants, and said mooring and anchoring system includes four continuous mooring line segments, one for each quadrant of the array.

11. The floating support structure of claim 10, wherein said mooring line segments are splayed radially to provide resistance for loading in the East-West direction and to provide torsional stability of the array, and further including anchor elements comprising one or more concrete deadman, a ground anchor, a pile, or any combination thereof.

12. The floating support structure of claim 10, wherein said mooring lines are pre-tensioned and released a fixed length at the time of installation.

13. The floating support structure of claim 10, wherein the connected array modules are arranged in a generally rectangular or square array geometry functionally divided into quadrants using a N-S axis an E-W axis as dividing lines so as to form NW, NE, SE, and SW quadrants, and wherein said mooring and anchoring system uses a single continuous running line for each of said four quadrants.

14. The floating support structure of claim 13, wherein each of said continuous running lines has a first end connected at a first continuous line connection point disposed on a corner of the array, extends outwardly from the array and is routed through a pulley disposed on a mooring buoy, back to the array, where it is either fed through a pulley mounted at the end of a N-S frame member or terminated at a second continuous line connection point.

15. The floating support structure of claim 14, wherein one buoy is provided for every two of said continuous line connection points on the array, said connection points either fixed connections or pulleys.

16. The floating support structure of claim 13, further including static cables connected to each of said mooring buoys and extending to shore.

17. The floating support structure of claim 2, wherein said coupling hardware includes a splice disposed between said E-W frame members of adjoin array modules, said splice configured and contoured to conform closely to the sides of said E-W frame members, wherein said E-W frame members include spaced-apart frame member insertion elements that cooperate with at least one corresponding splice insertion element disposed on said splice, such that as said splice is slidably mated to and between said E-W frame members of adjoining array modules, a frame member insertion element engages a corresponding splice insertion element to retain said splice and prevent it from being pulled apart from said frame member, and wherein said splice can then be further translated along said frame member and into further engagement with said frame member until said splice insertion element engages said a second frame member insertion element so as to hold said splice firmly in place.

18. The floating support structure of claim 17, wherein as said splice insertion element engages a first of said frame member insertion elements, said frame members are brought into substantial alignment and are held in place and prevented from separating as they are more fully approximated using said splice as an indexing element.

19. A method of assembling and launching connected array modules for a floating solar panel array, comprising the steps of:
(a) providing a conveyor system having a launch end proximate a body of water onto which connected solar panel array modules will be launched and an assembly end on which floating solar panel array modules will be assembled;
(b) providing a plurality of floatation elements;
(c) providing framework members for connecting and aligning said floatation elements;
(d) connecting and aligning said floatation elements with said framework members so as to form an array module and base for supporting one or more solar panels, the;
(e) mounting at least one solar panel on said array module;
(f) providing coupling hardware for connecting a framework members of one array module to an adjoining module assembled on the roller conveyor system;
(g) connecting at least one array module to an adjoining array module while the array modules are disposed on the conveyor system so as to form an array block; and
(h) launching the array block onto a body of water from the second end of the conveyor system.

20. The method of claim 19, wherein steps (a) through (h) are performed until a desired number of array blocks are deployed onto water, and further including the step of connecting the array blocks into unified floating solar panel array.

21. The method of claim 20, further including the step of connecting a mooring and anchoring system to the floating solar panel array, the mooring and anchoring system including a plurality of continuous running lines that produce equal force resistance to each point on the solar panel array to which the continuous running lines are attached.
